(19) United States
(12) Patent Application Publication
(10) Pub. No.: US 2025/0338601 A1
(43) Pub. Date: Oct. 30, 2025

(54) Trench Semiconductor Structure and Manufacturing Method Thereof

(71) Applicant: Diodes Incorporated, Plano, TX (US)

(72) Inventors: Ta-Chuan KUO, New Taipei City (TW); Chiao-Shun CHUANG, New Taipei City (TW)

(21) Appl. No.: 18/946,724

(22) Filed: Nov. 13, 2024

Related U.S. Application Data
(63) Continuation of application No. PCT/CN2024/093540, filed on May 16, 2024.

(30) Foreign Application Priority Data
Apr. 26, 2024 (CN) 202410509983.5

(51) Int. Cl. H01L 29/78; H01L 29/40; H01L 29/417; H01L 29/66

(52) U.S. Cl. CPC H10D 84/146; H10D 30/0295; H10D 30/0297; H10D 30/668; H10D 64/117; H10D 64/252

(57) ABSTRACT

A trench semiconductor structure includes a semiconductor material layer having a first surface and a second surface. A first trench structure extends from the first surface towards the second surface, and includes an electrode and a gate. The electrode includes a first portion and a second portion below the first portion and the gate. An interlayer dielectric layer is disposed on the first surface covering the first trench structure and a doped region in the semiconductor material layer. A shielding metal layer covers the interlayer dielectric layer and the fist doped region and contacts the electrode. A metal layer is disposed on the shielding metal layer. The first portion of the first electrode is located between the doped region and the gate. The electrode and the doped region contact the shielding metal layer and are electrically connected to the metal layer.

### CROSS-REFERENCE TO RELATED APPLICATIONS

This application is a continuation of International Application No. PCT/CN2024/093540, filed on May 16, 2024 and entitled “TRENCH SEMICONDUCTOR STRUCTURE AND MANUFACTURING METHOD THEREOF,” which claims priority to Chinese Patent Application No. 202410509983.5, filed on Apr. 26, 2024 and entitled “TRENCH SEMICONDUCTOR STRUCTURE AND MANUFACTURING METHOD THEREOF.” The aforementioned applications are hereby incorporated by reference herein as if reproduced in their entireties.

### TECHNICAL FIELD

The present disclosure relates generally to semiconductor technologies, and in particular, to a trench semiconductor structure and a manufacturing method thereof. Particular embodiments provide a trench metal oxide semiconductor (MOS) structure and a manufacturing method thereof.

### BACKGROUND

Modern power circuits require rectifiers that provide high power, low power loss and fast switching. Integration of a trench MOS barrier Schottky (TMBS) diode and a shielded gate trench metal-oxide-semiconductor field-effect transistor (SGT MOSFET or SGW-MOSFET) includes placing respectively the TMBS and the SGT MOSFET in different trenches, and positioning charge coupling between a main charge carrier in the terrace-shaped portion of the epitaxial/drift region and the metal on the insulating sidewalls of a trench. The charge coupling redistributes the electric field below the Schottky contact, thereby improving the breakdown voltage and reducing the reverse leakage current. The integration of the TMBS with the SGT-MOSFET can further reduce the resistance and gate capacitance, thereby reducing the power loss of the semiconductor power circuit and increasing the switching speed of the semiconductor power circuit.

Conventional methods for integrating the TMBS and the SGT MOSFET involve placing the TMBS and the SGT-MOSFET in adjacent areas of the same chip, which requires an additional chip area. Current manufacturing methods and power circuit structures lack efficiency and flexibility, and usually cause waste of chip areas, which increases production costs. Therefore, there is a need to further improve the device miniaturization technology for semiconductor structures in the art having TMBS and SGT MOSFET, in order to achieve desirable high power and low loss, and improve device performance.

### SUMMARY

Technical advantages are generally achieved, by embodiments of this disclosure which describe trench semiconductor structures and manufacturing methods thereof.

Embodiments of the present disclosure relate to a trench semiconductor structure. The trench semiconductor structure includes: a semiconductor material layer having a first surface and a second surface opposite to the first surface, wherein the semiconductor material layer has a first conductivity type; a first trench structure extending from the first surface towards the second surface, wherein the first trench structure includes a first electrode, a first gate, and a first oxide layer separating the first electrode from the first gate, the first electrode including a first portion adjacent to the first gate, and a second portion located below the first portion and the first gate and connected to the first portion; a first doped region located in the semiconductor material layer adjacent to the first surface and adjacent to the first portion of the first electrode, wherein the first doped region has a second conductivity type; an interlayer dielectric layer located on the first surface of the semiconductor material layer and covering the first trench structure; a shielding metal layer covering the interlayer dielectric layer and the first doped region and contacting the first electrode; and a metal layer located on the interlayer dielectric layer and the first doped region. The first portion of the first electrode is located between the first doped region and the first gate, and the first electrode and the first doped region are both in contact with the shielding metal layer to be electrically connected to the metal layer.

Embodiments of the present disclosure also relate to a trench semiconductor structure. The trench semiconductor structure includes: a semiconductor material layer having a first conductivity type and having a first region and a second region surrounding the first region; a first trench structure, which is recessed into the semiconductor material layer and includes a first electrode, a first gate, and a first oxide layer surrounding the first electrode and the first gate, wherein the first electrode includes a first portion adjacent to the first gate, and a second portion overlapping with the first portion and the first gate and connected to the first portion when viewed from a top view; a second trench structure, which is recessed into the semiconductor material layer and includes a second electrode, a second gate, and a second oxide layer surrounding the second electrode and the second gate; and a first doped region disposed in the semiconductor material layer and located between the first trench structure and the second trench structure, wherein the first doped region has a second conductivity type. The first electrode and the second electrode are disposed between the first gate and the second gate, a portion of the first electrode, a portion of the second electrode, and the first doped region between the first electrode and the second electrode are located in the first region, and the first gate and the second gate are located in the second region.

Embodiments of the present disclosure relate to a manufacturing method of a trench semiconductor structure. The manufacturing method of the trench semiconductor structure includes: forming a first trench in a semiconductor material layer, the first trench extending from a first surface towards a second surface; forming a first electrode in the first trench, the first electrode including a first portion and a second portion located below the first portion and connected to the first portion; forming a first gate in the first trench, the first gate being adjacent to the first portion of the first electrode and being located above the second portion of the first electrode, and the first electrode and the first gate forming a first trench structure; forming a first doped region in the semiconductor material layer adjacent to the first surface, wherein the first doped region has a second conductivity type, and the first portion of the first electrode is located between the first doped region and the first gate; forming an interlayer dielectric layer on the first surface of the semiconductor material layer, the interlayer dielectric layer covering the first trench structure and the first doped region; forming a groove extending through the interlayer dielectric layer, exposing the first doped region and the first portion of the first electrode; forming a shielding metal layer in the groove and on the interlayer dielectric layer, the shielding metal layer covering the interlayer dielectric layer and the first doped region and contacting the first portion of the first electrode; and forming a metal layer in the groove and on the interlayer dielectric layer and the shielding metal layer. The first portion of the first electrode and the first doped region are both in contact with the shielding metal layer to be electrically connected to the metal layer.

According to one aspect of the present disclosure, a trench semiconductor structure is provided that includes: a semiconductor material layer of a first conductivity type, the semiconductor material layer having a first surface and a second surface opposite to the first surface; a first trench structure extending from the first surface towards the second surface, wherein the first trench structure includes a first electrode, a first gate, and a first oxide layer separating the first electrode from the first gate, and the first electrode includes a first portion and a second portion connected to the first portion, the first portion being adjacent to the first gate, and the second portion located below the first portion and the first gate; a first doped region of a second conductivity type in the semiconductor material layer and adjacent to the first surface, wherein the first portion of the first electrode is located between the first doped region and the first gate; an interlayer dielectric layer, disposed on the first surface of the semiconductor material layer and covering the first trench structure; a shielding metal layer, covering the interlayer dielectric layer and the first doped region, and contacting the first electrode; and a metal layer, disposed on the shielding metal layer, and covering the interlayer dielectric layer and the first doped region, wherein the first electrode and the first doped region are in contact with the shielding metal layer and are electrically connected to the metal layer through the shielding metal layer.

According to one aspect of the present disclosure, a trench semiconductor structure is provided that includes: a semiconductor material layer of a first conductivity type, having a first region and a second region surrounding the first region; a first trench structure, recessed from a first surface of the semiconductor material layer into the semiconductor material layer, and comprising a first electrode, a first gate, and a first oxide layer surrounding and separating the first electrode and the first gate, wherein the first electrode includes a first portion and a second portion connected to the first portion, the first portion being adjacent to the first gate, and the second portion overlapping with the first portion and the first gate in a top view of the trench semiconductor structure; a second trench structure, recessed from the first surface of the semiconductor material layer into the semiconductor material layer, and comprising a second electrode, a second gate and a second oxide layer surrounding and separating the second electrode and the second gate; and a first doped region of a second conductivity type, disposed in the semiconductor material layer, and between the first trench structure and the second trench structure; and wherein the first electrode and the second electrode are disposed between the first gate and the second gate, a portion of the first electrode, a portion of the second electrode, and the first doped region are located in the first region, and the first gate and the second gate are located in the second region.

According to another aspect of the present disclosure, a method of manufacturing a trench semiconductor structure is provided that includes: forming a first trench in a semiconductor material layer of a first conductivity type, wherein the first trench extends from a first surface of the semiconductor material layer towards a second surface of the semiconductor material layer opposite to the first surface; forming a first electrode in the first trench, wherein the first electrode comprises a first portion, and a second portion located below the first portion and connected to the first portion; forming a first gate in the first trench, wherein the first gate is adjacent to the first portion of the first electrode and above the second portion of the first electrode, and the first electrode and the first gate form a first trench structure; forming a first doped region of a second conductivity type in the semiconductor material layer adjacent to the first surface, wherein the first portion of the first electrode is located between the first doped region and the first gate; forming an interlayer dielectric layer on the first surface of the semiconductor material layer, wherein the interlayer dielectric layer covers the first trench structure and the first doped region; forming a groove extending through the interlayer dielectric layer, the first groove exposing the first doped region and the first portion of the first electrode; forming a shielding metal layer in the groove and on the interlayer dielectric layer, wherein the shielding metal layer covers the interlayer dielectric layer and the first doped region; and forming a metal layer in the groove and on the shielding metal layer, wherein the first portion of the first electrode and the first doped region are in contact with the shielding metal layer and electrically connected to the metal layer.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of several embodiments of the present disclosure may be better understood when the following detailed description is read in conjunction with the accompanying drawings.

It should be noted that various structures may not be drawn to scale. In fact, the dimensions of various structures may be enlarged or reduced for clarity of discussion.

FIG. 1 is a top view of an example trench semiconductor structure according to some embodiments of the present disclosure;

FIG. 2 is a cross-sectional view of the trench semiconductor structure along a line AA′ shown in FIG. 1 according to some embodiments of the present disclosure;

FIG. 3 is a top view of another example trench semiconductor structure according to some embodiments of the present disclosure;

FIG. 4 is a top view of another example trench semiconductor structure according to some embodiments of the present disclosure;

FIG. 5 is a cross-sectional view of another example trench semiconductor structure according to some embodiments of the present disclosure;

FIG. 6 is a cross-sectional view of another example trench semiconductor structure according to some embodiments of the present disclosure;

FIG. 7 is a cross-sectional view of another example trench semiconductor structure according to some embodiments of the present disclosure;

FIG. 8 is a cross-sectional view of another example trench semiconductor structure according to some embodiments of the present disclosure;

FIG. 9 is a cross-sectional view of another example trench semiconductor structure according to some embodiments of the present disclosure; and

FIG. 10 to FIG. 34 show one or more stages in an example method for manufacturing a trench semiconductor structure according to some embodiments of the present disclosure.

The same or similar components are marked with the same reference numerals and symbols in the drawings and detailed description. The figures are drawn to clearly illustrate the relevant aspects of the embodiments and are not necessarily drawn to scale. Embodiments of the present disclosure will be readily understood from the following detailed description in conjunction with the accompanying drawings.

### DETAILED DESCRIPTION OF ILLUSTRATIVE EMBODIMENTS

The following disclosure provides many different embodiments or examples for implementing the different features of the provided subject matter. Specific examples of components and configurations are described below. Certainly, these are only examples and are not intended to be limiting. In the present disclosure, references to forming a first feature above or on a second feature may include embodiments in which the first feature and the second feature are formed to be in direct contact, and may also include embodiments in which additional features may be formed between the first feature and the second feature so that the first feature and the second feature may not be in direct contact. In addition, the present disclosure may repeat reference symbols and/or letters in various examples. This repetition is for simplicity and clarity and does not itself indicate the relationship between the various embodiments and/or configurations discussed.

The following is a detailed discussion of embodiments of the present disclosure. However, it should be understood that the present disclosure provides many applicable concepts that can be embodied in a variety of specific environments and contexts. The specific embodiments discussed are merely illustrative and do not limit the scope of the present disclosure.

Further, it should be understood that various changes, substitutions and alterations can be made herein without departing from the spirit and scope of this disclosure as defined by the appended claims. Furthermore, one or more features from one or more of the following described embodiments may be combined to create alternative embodiments not explicitly described, and features suitable for such combinations are understood to be within the scope of this disclosure. It is therefore intended that the appended claims encompass any such modifications or embodiments.

Embodiments of the present disclosure provide a trench semiconductor structure and a manufacturing method thereof. In the embodiment trench semiconductor structure of the present disclosure, a TMBS diode is integrated with an SGT MOSFET, the distance between the TMBS and the SGT MOSFET is generally minimized, the chip area utilization is improved, and the chip space is saved.

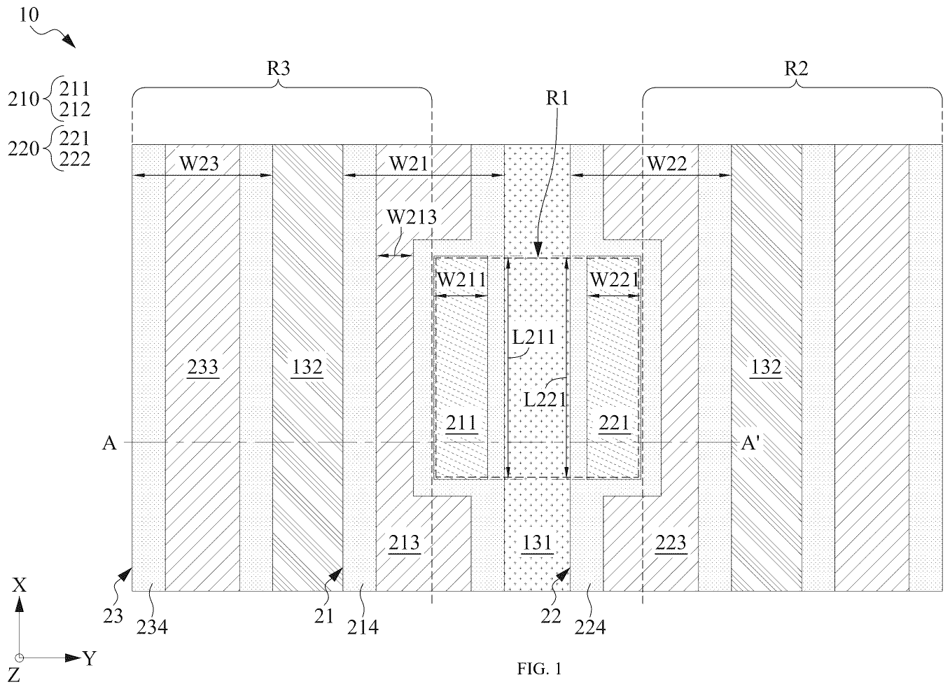

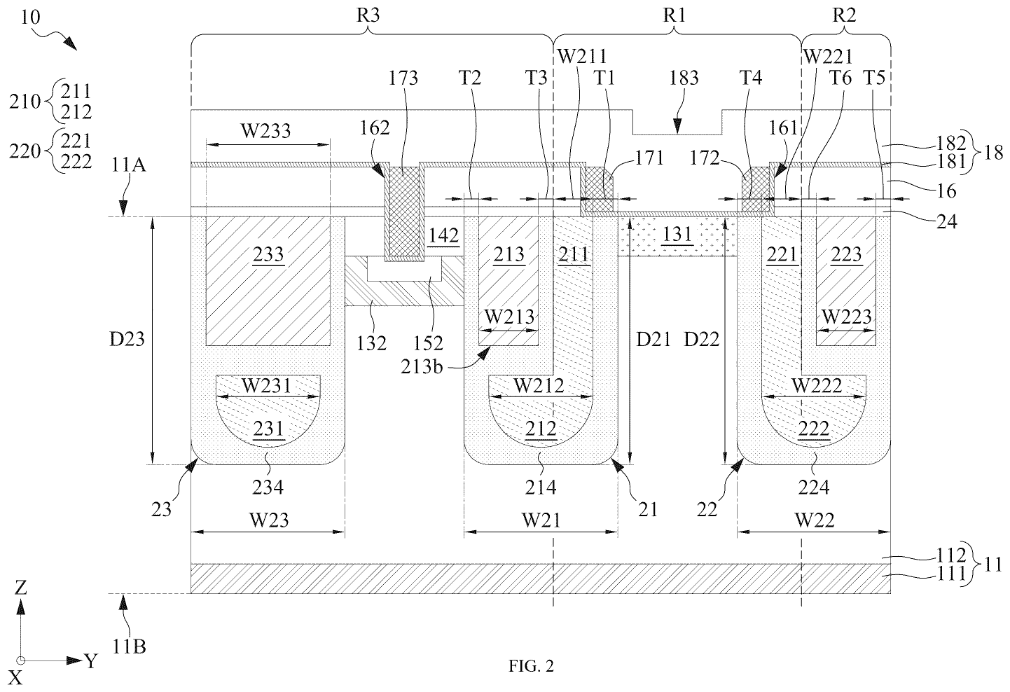

FIG. 1 is a top view of an example of a trench semiconductor structure 10 according to some embodiments of the present disclosure. FIG. 2 is a cross-sectional view of the trench semiconductor structure 10 along a line AA′ in FIG. 1 according to some embodiments of the present disclosure. Specifically, the trench semiconductor structure 10 is a trench MOSFET structure having a vertical current conduction path. For example, the current of the trench semiconductor structure 10 can be conducted vertically through the trench semiconductor structure 10.

In some embodiments, referring to FIG. 1 and FIG. 2, the trench semiconductor structure 10 includes a semiconductor material layer 11, a first trench structure 21, a second trench structure 22, a first doped region 131, an interlayer dielectric layer 16 and a conductive material layer 18. In some embodiments, the trench semiconductor structure 10 may further include a third trench structure 23, a second doped region 132, and a third doped region 142.

In some embodiments, the semiconductor material layer 11 includes a substrate 111 and an epitaxial layer 112 located on the substrate 111. In some embodiments, the substrate 111 includes, for example, silicon, silicon carbide (SiC), germanium (Ge), silicon germanium (SiGe), gallium nitride (GaN), gallium arsenide (GaAs), gallium arsenide phosphide (GaAsP), or other semiconductor materials. In some embodiments, the epitaxial layer 112 includes, for example, silicon, silicon carbide, germanium, silicon germanium, gallium nitride, gallium arsenide, gallium arsenide phosphide, or other semiconductor materials. The substrate 111 may be an N-type or P-type semiconductor material. The epitaxial layer 112 may be an N-type or P-type semiconductor material. In some embodiments, the substrate 111 and the epitaxial layer 112 have the same conductivity type, for example, the substrate 111 and the epitaxial layer 112 are both N-type.

The substrate 111 has doping of the same conductivity type as the epitaxial layer 112. In some embodiments, the substrate 111 may be part of a silicon substrate or a silicon wafer. In some embodiments, the doping concentration of the substrate 111 may be greater than the doping concentration of the epitaxial layer 112.

In some embodiments, the semiconductor material layer 11 may be defined with a first region R1 and a second region R2 adjacent to the first region R1 as shown in the top view. The first region R1 may include a TMBS, and the second region R2 may include an SGT MOSFET. In some embodiments, the semiconductor material layer 11 may further be defined with a third region R3 adjacent to the first region RI as shown in the top view. In some embodiments, the first region R1 may be located between the second region R2 and the third region R3, or surrounded by the second region R2 and the third region R3, and the third region R3 may also include an SGT MOSFET.

The semiconductor material layer 11 may have a first surface 11A and a second surface 11B opposite to the first surface 11A. The second surface 11B and the first surface 11A may be located on opposite sides of the semiconductor material layer 11. The first surface 11A and the second surface 11B may be horizontal planes. For convenience of description, the direction perpendicular to the first surface 11A and the second surface 11B is defined as a vertical direction Z, and the plane formed by a first direction X and a second direction Y is perpendicular to the vertical direction Z. In some embodiments, the first surface 11A may be the active surface of the epitaxial layer 112. The bottom surface of the substrate 111 is the second surface 11B.

The first trench structure 21 is recessed into the semiconductor material layer 11 and extends from the first surface 11A towards the second surface 11B. The first trench structure 21 includes a first electrode 210, a first gate 213, and a first oxide layer 214 separating the first electrode 210 from the first gate 213. The first electrode 210 includes a first portion 211 and a second portion 212 connected to the first portion 211. The first portion 211 is adjacent to the first gate 213. The second portion 212 is located below the first portion 211 and the first gate 213. In some embodiments, the first portion 211 and the second portion 212 of the first electrode 210 are integrally formed. The first portion 211 of the first electrode 210 is located between the first gate 213 and the first doped region 131. In some embodiments, the first gate 213 is a columnar structure.

In some embodiments, the top surface of the first trench structure 21 is coplanar with the first surface 11A. In some embodiments, the top surface of the first electrode 210 and the top surface of the first gate 213 are coplanar with the first surface 11A. In the top view, the first trench structure 21 extends in the first direction X parallel to the first surface 11A. The first portion 211 of the first electrode 210 and the first gate 213 overlap with the second portion 212 of the first electrode 210 below.

The first oxide layer 214 is used to electrically isolate the epitaxial layer 112 from the first electrode 210 and the first gate 213. In other words, the first electrode 210 and the first gate 213 are separated from the epitaxial layer 112 by the first oxide layer 214 in the trench of the first trench structure 21. The first electrode 210 and the first gate 213 are respectively surrounded by the first oxide layer 214. At least a portion of the first oxide layer 214 is located between the first electrode 210 and the first gate 213. At least a portion of the first oxide layer 214 serves as a gate oxide layer of the SGT MOSFET located in the third region R3. In some embodiments, the first oxide layer 214 located between the first portion 211 of the first electrode 210 and the semiconductor material layer 11 has a first thickness T1, and the first oxide layer 214 located between the first gate 213 and the semiconductor material layer 11 has a second thickness T2. In some embodiments, the second thickness T2 may be less than the first thickness T1. In some embodiments, the first thickness T1 and the second thickness T2 may be generally the same. The first thickness T1 and the second thickness T2 may respectively be adjusted according to the sizes or operating voltages of the first electrode 210 and the first gate 213.

In some embodiments, the first portion 211 of the first electrode 210 has a first width W211, the second portion 212 of the first electrode 210 has a second width W212, and the first width W211 is smaller than the second width W212. The first gate 213 has a third width W213, and the third width W213 may be greater than or equal to the first width W211. In some embodiments, the first width W211 may be generally the same as the third width W213. In some embodiments, the second width W212 is greater than the third width W213, and the third width W213 is greater than the first width W211. In some embodiments, the sum of the first width W211 and the third width W213 is greater than or equal to the second width W212 of the second portion 212 of the first electrode 210.

The semiconductor material layer 11 includes the first doped region 131. The first doped region 131 may extend in the first direction X in the top view. In some embodiments, the first doped region 131 is disposed between the first surface 11A and the second surface 11B, adjacent to the first oxide layer 214 and separated from the first electrode 210. The first doped region 131 is located in the semiconductor material layer 11 adjacent to the first surface 11A and adjacent to the first trench structure 21. In some embodiments, the first doped region 131 is located in the epitaxial layer 112 and in contact with the first oxide layer 214. At least a portion of the first oxide layer 214 is located between the first electrode 210 and the first doped region 131. In some embodiments, the top of the first doped region 131 is in contact with or coplanar with the first surface 11A.

In some embodiments, the first doped region 131 serves as a doped body region of the trench semiconductor structure 10. At least a portion of the epitaxial layer 112 is disposed between the first doped region 131 and the substrate 111. In some embodiments, the first doped region 131 has a conductivity type different from that of the epitaxial layer 112, for example, having a conductivity type of a second type. In some embodiments, the first doped region 131 is of P-type, and the epitaxial layer 112 is of N-type. The first doped region 131 contains a P-type dopant, and the P-type dopant may be, for example, boron, aluminum, gallium, indium, and so on. In some embodiments, the P-type dopant contained in the first doped region 131 is boron. The doping concentration of the first doped region 131 may be greater than the doping concentration of the epitaxial layer 112. The depth of the first doped region 131 may be less than the depth of the bottom surface 213b of the first gate 213. The first doped region 131 is electrically connected to the conductive material layer 18.

The second trench structure 22 is spaced apart from the first trench structure 21. The first doped region 131 may be located between the first trench structure 21 and the second trench structure 22. In an example, sidewalls of the first doped region 131 may be in contact with the first trench structure 21 and the second trench structure 22, respectively. The trench depth of the first trench structure 21 and the trench depth of the second trench structure 22 may be the same or different, and the trench width W21 of the first trench structure 21 and the trench width W22 of the second trench structure 22 may be the same or different. In some embodiments, the trench depth D21 of the first trench structure 21 may be the same as the trench depth D22 of the second trench structure 22. The trench width W21 of the first trench structure 21 may be the same as the trench width W22 of the second trench structure 22.

The second trench structure 22 is recessed into the semiconductor material layer 11 and extends from the first surface 11A towards the second surface 11B. The second trench structure 22 includes a second electrode 220, a second gate 223, and a second oxide layer 224 separating the second electrode 220 from the second gate 223. The second electrode 220 includes a third portion 221 and a fourth portion 222 connected to the third portion 221. The third portion 221 is adjacent to the second gate 223. The fourth portion 222 is located below the third portion 221 and the second gate 223. In some embodiments, the third portion 221 and the fourth portion 222 of the second electrode 220 are integrally formed. The third portion 221 of the second electrode 220 is located between the second gate 223 and the first doped region 131. In some embodiments, the second gate 223 is a columnar structure.

In some embodiments, the top surface of the second trench structure 22 is coplanar with the first surface 11A. In some embodiments, the top surface of the second electrode 220 and the top surface of the second gate 223 are coplanar with the first surface 11A. In the top view, the second trench structure 22 extends in the first direction X parallel to the first surface 11A, and the third portion 221 of the second electrode 220 and the second gate 223 overlap with the fourth portion 222 of the second electrode 220 below.

The second oxide layer 224 is used to electrically isolate the epitaxial layer 112 from the second electrode 220 and the second gate 223. In other words, the second electrode 220 and the second gate 223 are separated from the epitaxial layer 112 by the second oxide layer 224 in the trench of the second trench structure 22. The second electrode 220 and the second gate 223 are respectively surrounded by the second oxide layer 224. At least a portion of the second oxide layer 224 is located between the second electrode 220 and the second gate 223. At least a portion of the second oxide layer 224 may serve as a gate oxide layer of the SGT MOSFET located in the second region R2. In some embodiments, the second oxide layer 224 located between the third portion 221 and the semiconductor material layer 11 has a fourth thickness T4, the second oxide layer 224 located between the second gate 223 and the semiconductor material layer 11 has a fifth thickness T5. The fifth thickness T5 may be less than the fourth thickness T4. In some embodiments, the fourth thickness T4 and the fifth thickness T5 may be substantially the same. The fourth thickness T4 and the fifth thickness T5 may respectively be adjusted according to the sizes or operating voltages of the second electrode 220 and the second gate 223.

In some embodiments, the third portion 221 of the second electrode 220 has a fourth width W221, the fourth portion 222 of the second electrode 220 has a fifth width W222, and the fourth width W221 is less than the fifth width W222. The second gate 223 has a sixth width W223, and the sixth width W223 may be greater than or equal to the fourth width W221. In some embodiments, the fourth width W221 may be substantially the same as the sixth width W223. In some embodiments, the fifth width W222 is greater than the sixth width W223, and the sixth width W223 is greater than the fourth width W221. In some embodiments, the sum of the fourth width W221 and the sixth width W223 is greater than or equal to the fifth width W222 of the fourth portion 222 of the second electrode 220.

The trench semiconductor structure 10 may include a TMBS. In some embodiments, the TMBS of the trench semiconductor structure 10 may be located in the first region R1. The TMBS may include the first electrode 210, the second electrode 220 and the first doped region 131. The TMBS extends from the first region R1 to below the first gate 213 and the second gate 223 through the configuration of the first electrode 210 and the second electrode 220, where the first gate 213 is located in the third region R3, and the second gate 223 is located in the second region R2. The first electrode 210, the second electrode 220, and the first doped region 131 form a TMBS diode. The first portion 211 of the first electrode 210, the third portion 221 of the second electrode 220, and the first doped region 131 located between the first electrode 210 and the second electrode 220 are located in the first region R1. The first portion 211 of the first electrode 210 and the third portion 221 of the second electrode 220 are disposed between the first gate 213 and the second gate 223. From the top view, the length L211 of the first portion 211 of the first electrode 210 along the first direction X and the length L221 of the third portion 221 of the second electrode 220 along the first direction X may be the same. In some embodiments, the TMBS may be surrounded by the second region R2 including the SGT MOSFET and by the third region R3. In the embodiment trench semiconductor structure 10 of the present disclosure, the TMBS and the SGT MOSFET are integrated into the first trench structure 21, where the first electrode 210 may be used as the source or shielding electrode of the TMBS, and the first gate 213 may be used as the gate of the SGT MOSFET. A portion of the first trench structure 21 belongs to the first region R1, and another portion of the first trench structure 21 belongs to the third region R3.

The semiconductor material layer 11 may form a mesa surface between the first trench structure 21 and the second trench structure 22. In some embodiments, the mesa surface separates the first trench structure 21 from the second trench structure 22. The width of the mesa surface may be controlled by the positions of the first trench structure 21 and the second trench structure 22. In some embodiments, the mesa surface is in the first region R1.

The third trench structure 23 is spaced apart from the first trench structure 21. The trench depth D21 of the first trench structure 21 and the trench depth D23 of the third trench structure 23 may be the same or different, and the trench width W21 of the first trench structure 21 and the trench width W23 of the third trench structure 23 may be the same or different. In some embodiments, the trench depth D21 of the first trench structure 21 is the same as the trench depth D23 of the third trench structure 23, and the trench width W21 of the first trench structure 21 is the same as the trench width W23 of the third trench structure 23.

The third trench structure 23 is recessed into the semiconductor material layer 11, extends from the first surface 11A towards the second surface 11B, and is disposed adjacent to the first trench structure 21. The third trench structure 23 includes a third electrode 231, a third gate 233 located over the third electrode 231, and a third oxide layer 234 separating the third electrode 231 and the third gate 233 from each other. In some embodiments, the third electrode 231 and the third gate 233 are columnar structures, respectively. In some embodiments, the top surface of the third trench structure 23 is coplanar with the first surface 11A. In some embodiments, the top surface of the third gate 233 is coplanar with the first surface 11A. From the top view, the third trench structure 23 extends in the first direction X parallel to the first surface 11A, and the third gate 233 overlaps with the third electrode 231 below.

The third oxide layer 234 is used to electrically isolate the third electrode 231 and the third gate 233 from the epitaxial layer 112. In other words, the third electrode 231 and the third gate 233 are separated from the epitaxial layer 112 via the third oxide layer 234 in the trench of the third trench structure 23. The third electrode 231 and the third gate 233 are respectively surrounded by the third oxide layer 234. At least a portion of the third oxide layer 234 is located between the third electrode 231 and the third gate 233. At least a portion of the third oxide layer 234 serves as a gate oxide layer of the SGT MOSFET located in the third region R3.

In some embodiments, the third electrode 231 has a seventh width W231, the third gate 233 has an eighth width W233, the seventh width W231 is substantially the same as the eighth width W233. In some embodiments, the seventh width W231 is smaller than the eighth width W233.

The second doped region 132 is located between the first trench structure 21 and the third trench structure 23, and extends in the first direction X in the top view. In some embodiments, the second doped region 132 is disposed between the first surface 11A and the second surface 11B, adjacent to the first oxide layer 214, and separated from the first gate 213. At least a portion of the first oxide layer 214 is located between the first gate 213 and the second doped region 132. In some embodiments, the second doped region 132 is located in the epitaxial layer 112 and contacts the first oxide layer 214 and the third oxide layer 234. The second doped region 132 is located in the semiconductor material layer 11 and adjacent to the first surface 11A, where the second doped region 132 has a second conductivity type, and the first trench structure 21 is located between the first doped region 131 and the second doped region 132.

The second doped region 132 is disposed between the first trench structure 21 and the third trench structure 23, and serves as a doped body region of the trench semiconductor structure 10. At least a portion of the epitaxial layer 112 is disposed between the second doped region 132 and the substrate 111. In some embodiments, the second doped region 132 has a conductivity type different from that of the epitaxial layer 112, for example, having a conductivity type of the second type. In some embodiments, the second doped region 132 is P-type, and the epitaxial layer 112 is N-type. The second doped region 132 includes a P-type dopant, and the P-type dopant may be, for example, boron, aluminum, gallium, indium, and so on. In some embodiments, the P-type dopant included in the second doped region 132 is boron. The doping concentration of the second doped region 132 may be greater than the doping concentration of the epitaxial layer 112. In some embodiments, the doping concentration of the second doped region 132 is different from the doping concentration of the first doped region 131. In some embodiments, the doping concentration of the second doped region 132 is greater than the doping concentration of the first doped region 131. For example, the doping concentration of the second doped region 132 may be, for example but not limited to, one order of magnitude greater than the doping concentration of the first doped region 131. The depth of the second doped region 132 may be less than the depth of the bottom surface 213b of the first gate 213. The depth of the second doped region 132 may be the same as or different from the depth of the first doped region 131. In some embodiments, the depth of the second doped region 132 is greater than the depth of the first doped region 131. The doping concentration and depth of the second doped region 132 and the doping concentration and depth of the first doped region 131 may be adjusted independently. The forward current and reverse leakage of the TMBS of the trench semiconductor structure 10 (e.g., the TMBS formed by the first electrode 210, the second electrode 220 and the first doped region 131) may be controlled by adjusting the doping concentration of the first doped region 131.

The semiconductor material layer 11 further includes the third doped region 142. The third doped region 142 extends in the first direction X in the top view. In some embodiments, the third doped region 142 is located between the first surface 11A and the second doped region 132, adjacent to the first oxide layer 214 and separated from the first gate 213. The third doped region 142 is located in the semiconductor material layer 11, adjacent to the first surface 11A and adjacent to the first trench structure 21. In some embodiments, the third doped region 142 is located in the epitaxial layer 112 and in contact with the first oxide layer 214. At least a portion of the first oxide layer 214 is located between the first gate 213 and the third doped region 142.

The third doped region 142 is disposed between the first trench structure 21 and the third trench structure 23, and serves as the source of the trench semiconductor structure 10. In some embodiments, the third doped region 142 has the same conductivity type as the epitaxial layer 112, for example, having the conductivity type of the first type. In some embodiments, the third doped region 142 and the epitaxial layer 112 have the N-type. The doping concentration of the third doped region 142 may be greater than the doping concentration of the epitaxial layer 112.

The depth of the third doped region 142 may be less than the depth of the bottom surface 213b of the first gate 213. The depth of the third doped region 142 may be less than the depth of the second portion 212 of the first electrode 210.

The interlayer dielectric layer 16 is located on the first surface 11A of the semiconductor material layer 11. The interlayer dielectric layer 16 is used to separate the conductive material layer 18 located on the interlayer dielectric layer 16 from the semiconductor material layer 11, the first trench structure 21, the second trench structure 22, and the third trench structure 23. The interlayer dielectric layer 16 covers the first trench structure 21, the second trench structure 22, the third trench structure 23, the first doped region 131, and the third doped region 142.

In some embodiments, a fourth oxide layer 24 may be disposed between the first surface 11A of the semiconductor material layer 11 and the interlayer dielectric layer 16. The fourth oxide layer 24 may be located between the interlayer dielectric layer 16 and the first trench structure 21, the second trench structure 22, the third trench structure 23, and the third doped region 142. In some embodiments, the fourth oxide layer 24 and the first oxide layer 214, the second oxide layer 224, and the third oxide layer 234 include the same or different materials. The thickness T24 of the fourth oxide layer 24 may be less than the second thickness T2 of the first oxide layer 214 located between the first gate 213 and the semiconductor material layer 11.

A first groove (or opening) 161 and a second groove (or opening) 162 extend through the interlayer dielectric layer 16 and the fourth oxide layer 24. The first groove 161 is located in the first region R1, and may be located on the first doped region 131, the first electrode 210 and the second electrode 220. The second groove 162 is located in the third region R3, and may be located on the third doped region 142 and extend into the semiconductor material layer 11. Each of the first groove 161 and the second groove 162 includes two opposing sidewalls and a bottom between the two opposing sidewalls. In some embodiments, at least a portion of the first electrode 210 and at least a portion of the second electrode 220 are exposed from the first groove 161. The width of the first groove 161 may be greater than the width of the second groove 162. The depth of the first groove 161 may be less than the depth of the second groove 162.

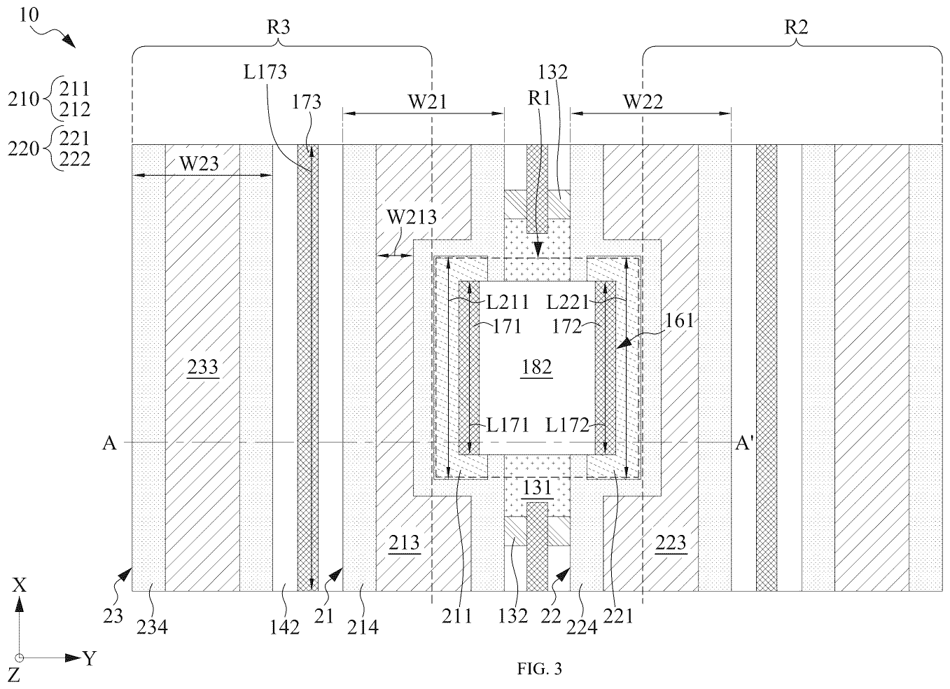

FIG. 3 is a top view of another example of the trench semiconductor structure 10 according to some embodiments of the present disclosure. In some embodiments, referring to FIG. 1, FIG. 2 and FIG. 3, the trench semiconductor structure 10 includes the conductive material layer 18 disposed on the interlayer dielectric layer 16 and the first doped region 131, and at least a portion of the conductive material layer 18 is disposed in the first groove 161. The conductive material layer 18 may be disposed on the top surface of the interlayer dielectric layer 16 and filled in the first groove 161. The first electrode 210, the second electrode 220 and the first doped region 131 are all electrically connected to the conductive material layer 18.

In some embodiments, the conductive material layer 18 may be the source of the trench semiconductor structure 10. In some embodiments, the conductive material layer 18 may be a patterned metal wire layer for adjusting the electrical path according to actual operation requirements, and include a plurality of metal wires for electrically connecting to different electrodes or doped regions. In some embodiments, the conductive material layer 18 may be the first metal layer (M1) in an interconnect structure. The conductive material layer 18 includes a conductive material, such as a metal, for example but not limited to, molybdenum (Co), copper (Cu), gold (Au), silver (Ag), aluminum (Al), nickel (Ni), titanium (Ti), tungsten (W), tin (Sn), titanium nitride (TiN), aluminum silicon (AlSi) alloy, aluminum silicon copper (AlSiCu) alloy or other metals or alloys. In some embodiments, the conductive material layer 18 includes a shielding metal layer 181 and a metal layer 182 located on the shielding metal layer 181.

In some embodiments, the shielding metal layer 181 covers the interlayer dielectric layer 16 and is conformally located in the first groove 161 and the second groove 162. The shielding metal layer 181 is located between the interlayer dielectric layer 16 and the metal layer 182. The first electrode 210, the second electrode 220, and the first doped region 131 are all in contact with the shielding metal layer 181 to be electrically connected to the metal layer 182. The shielding metal layer 181 covers the interlayer dielectric layer 16, the first doped region 131, and the inner side surfaces of the first groove 161 and the second groove 162 (including the opposing sidewalls and the bottom extending between the sidewalls). The shielding metal layer 181 located in the first groove 161 contacts the interlayer dielectric layer 16, the fourth oxide layer 24, the first portion 211 of the first electrode 210, and the third portion 221 of the second electrode. The shielding metal layer 181 in the second groove 162 contacts the interlayer dielectric layer 16, the fourth oxide layer 24, the second doped region 132 and the third doped region 142. The second electrode 220 contacts the shielding metal layer 181 to be electrically connected to the metal layer 182. The shielding metal layer 181 may include molybdenum, copper or titanium.

The metal layer 182 covers the shielding metal layer 181. The first electrode 210 and the first doped region 131 are in contact with the shielding metal layer 181 and are electrically connected to the metal layer 182. In some embodiments, the metal layer 182 includes a recess 183. The recess 183 may be located over the first groove 161, and the position and size of the recess 183 correspond to the position and size of the first groove 161.

In some embodiments, the shielding metal layer 181 has a notch/opening (not shown) on the first doped region 131, and the metal layer 182 is located in the notch and contacts the first doped region 131 through the notch. As an example, the opening exposes a portion of the first doped region 131, and the metal layer 182 completely fills in the opening so as to be in contact with the first doped region 131.

The first electrode 210, the second electrode 220 and the first doped region 131 may be electrically connected to the metal layer 182, respectively. In some embodiments, a first conductive plug 171 and a second conductive plug 172 are located in the first groove 161. The first conductive plug 171 is located on the first portion 211 of the first electrode 210 and electrically connected to the first electrode 210 and the conductive material layer 18. The second conductive plug 172 is located on the third portion 221 of the second electrode 220 and electrically connected to the second electrode 220 and the conductive material layer 18. The first conductive plug 171 and the second conductive plug 172 are located on two sides of the first groove 161 and electrically connected to the first electrode 210 and the second electrode 220, respectively. The characteristics of the TMBS of the trench semiconductor structure 10, such as the magnitude of the reverse leakage current and the magnitude of the turn on voltage, and so on, depend on the concentration of the first doped region 131, the width W161 of the first groove 161, and the area of the first groove 161 when viewed from the top view of FIG. 3.

The first conductive plug 171 and the second conductive plug 172 may be located on the shielding metal layer 181 and separated from each other by the metal layer 182. At least a portion of the metal layer 182 is located between the first conductive plug 171 and the second conductive plug 172. The first conductive plug 171 and the second conductive plug 172 may both extend through the interlayer dielectric layer 16 and the fourth oxide layer 24, and be respectively adjacent to the interlayer dielectric layer 16 and the fourth oxide layer 24. The first conductive plug 171 and the second conductive plug 172 are separated from each other and both are located between the shielding metal layer 181 and the metal layer 182. The first conductive plug 171, the second conductive plug 172 and at least a portion of the metal layer 182 in the first groove 161 are surrounded by the shielding metal layer 181. In some embodiments, the first conductive plug 171 and the second conductive plug 172 have arc-shaped top surfaces. In some embodiments, the top surfaces of the first conductive plug 171 and the second conductive plug 172 are not coplanar with the top surface of the shielding metal layer 181. For example, the top surfaces of the first conductive plug 171 and the second conductive plug 172 are lower than the top surface of a portion of the shielding metal layer 181 that is located on the top surface of the interlayer dielectric layer 16.

The first conductive plug 171 and the second conductive plug 172 are located above the first surface 11A of the semiconductor material layer 11. From the top view of FIG. 3, the first conductive plug 171 and the second conductive plug 172 are located in the first region R1 and extend in the first direction X. The length L171 of the first conductive plug 171 along the first direction X is less than the length L211 of the first electrode 210 along the first direction X. The length L172 of the second conductive plug 172 along the first direction X is less than the length L221 of the second electrode 220 along the first direction X.

The second doped region 132 may be electrically connected to the metal layer 182. In some embodiments, a third conductive plug 173 may be located in the second groove 162 and electrically connected to the second doped region 132 and the metal layer 182. The third conductive plug 173 may extend through the interlayer dielectric layer 16 and the fourth oxide layer 24, and is surrounded by the shielding metal layer 181. The third conductive plug 173 may further extend from above the first surface 11A of the semiconductor material layer 11 towards the second surface 11B along the vertical direction Z. The first gate 213, the third electrode 231, the third gate 233, the second doped region 132, the third doped region 142 and the third conductive plug 173 form a SGT MOSFT, in the third region R3. In some embodiments, the top surface of the third conductive plug 173 is not coplanar with the top surface of the shielding metal layer 181. For example, the top surface of the third conductive plug 173 is lower than the top surface of a portion of the shielding metal layer 181 that is located on the top surface of the interlayer dielectric layer 16. From the top view of FIG. 3, the third conductive plug 173 is located in the third region R3 and extends in the first direction X. The length L171 of the first conductive plug 171 along the first direction X is smaller than the length L173 of the third conductive plug 173 along the first direction X.

A heavily doped region 152 may be provided in the second doped region 132. The heavily doped region 152 has the same conductivity type as the second doped region 132, for example, P-type. In some embodiments, the doping concentration of the heavily doped region 152 is greater than the doping concentration of the second doped region 132. In some embodiments, the heavily doped region 152 is located in the second doped region 132 and is separated from the first oxide layer 214 and the third oxide layer 234. In some embodiments, the heavily doped region 152 is disposed between the adjacent second doped region 132 and the third doped region 142. The heavily doped region 152 is located below the third conductive plug 173. A portion of the heavily doped region 152 may be located between the third conductive plug 173 and the first trench structure 21, and another portion of the heavily doped region 152 may be located between the third conductive plug 173 and the third trench structure 23. In other words, the heavily doped region 152 surrounds the bottom of the third conductive plug 173 disposed in the second doped region 132, to reduce the ohmic contact resistance. Thus, the second groove 162 extends through the interlayer dielectric layer 16, the fourth oxide layer 24 and the third doped region 142, and extends into the heavily doped region 152.

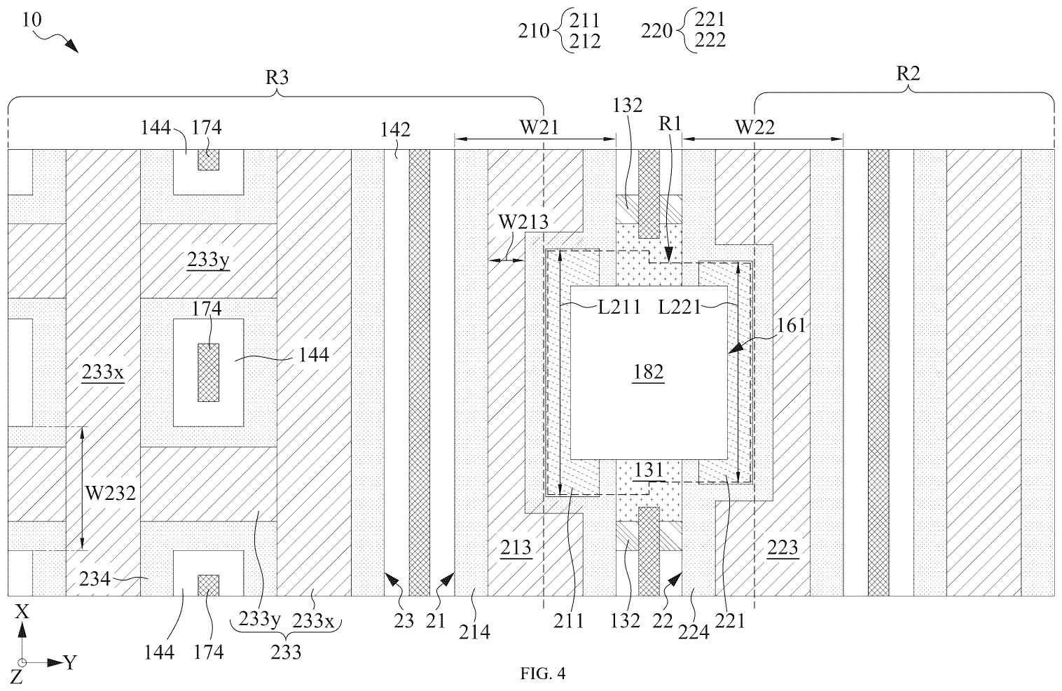

FIG. 4 is a top view of another example of the trench semiconductor structure 10 according to some embodiments of the present disclosure. In some embodiments, referring to FIG. 4, from the top view of FIG. 4, the third gate 233 may is in a mesh structure. The third gate 233 may include a fifth portion 233x extending along the first direction X and a sixth portion 233y extending along the second direction Y different from the first direction X. In some embodiments, the third gate 233 may include a plurality of fifth portions 233x and a plurality of sixth portions 233y. In some embodiments, the first direction X is orthogonal/perpendicular to the second direction Y.

In some embodiments, a plurality of fourth doped regions 144 may be disposed in the mesh structure. Each fourth doped region 144 may be surrounded by the fifth portions 233x and the sixth portions 233y of the third gate 233 and by the third oxide layer 234. Each fourth doped region 144 is electrically connected to the metal layer 182. In some embodiments, the trench semiconductor structure 10 includes a plurality of fourth conductive plugs 174 corresponding to the plurality of fourth doped regions 144, and each fourth doped region 144 is electrically connected to the metal layer 182 by a corresponding fourth conductive plug 174.

In some embodiments, the length L211 of the first portion 211 of the first electrode 210 along the first direction X and the length L221 of the third portion 221 of the second electrode 220 along the first direction X may be different. For example, the length L211 may be greater than the length L221.

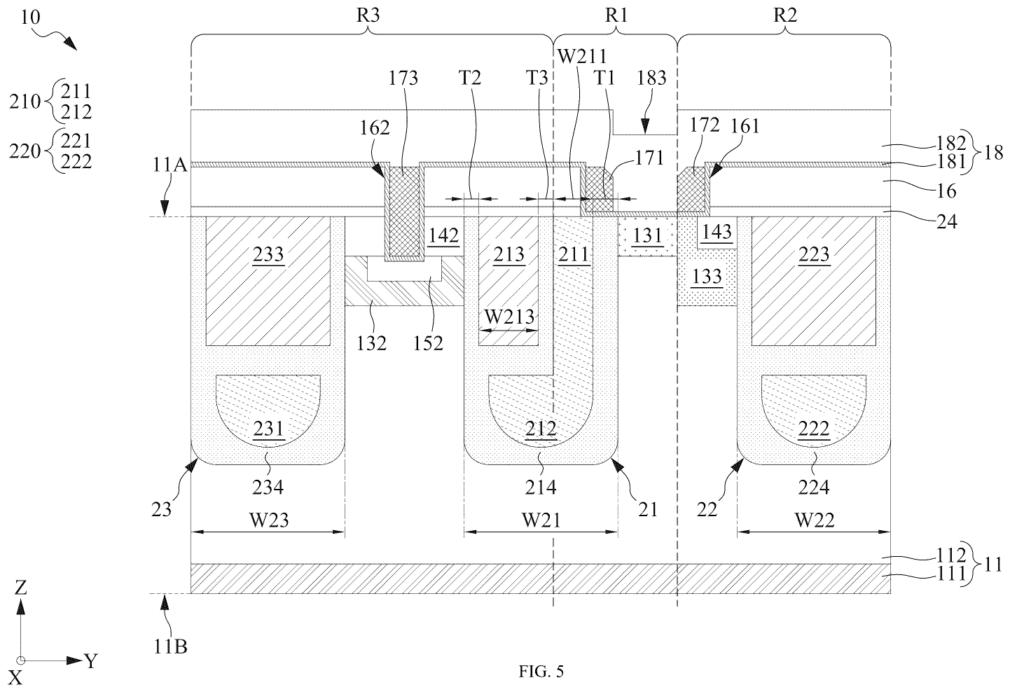

FIG. 5 is a cross-sectional view of another example of the trench semiconductor structure 10 according to some embodiments of the present disclosure. The example trench semiconductor structure 10 in FIG. 5 has some different structures from that shown in FIG. 2, as described in the following. Specifically, in some embodiments, a portion of the mesa surface between the first trench structure 21 and the second trench structure 22 belongs to the first region R1, and the second trench structure 22 and the remaining portion of the mesa surface belong to the second region R2. In some embodiments, the second electrode 220 is located below the second gate 223, and the second electrode 220 has only the fourth portion 222. In some embodiments, the structure of the TMBS (as formed by the first electrode 210, the second electrode 220 and the doped region 131) may be asymmetric, and may be a single-sided structure as shown in FIG. 5. In an example, a portion of the mesa surface between the first trench structure 21 and the second trench structure 22 belongs to the TMBS, and another portion of the mesa surface belongs to the SGT MOSFET in the second region R2 which is to be described later. Compared with the trench semiconductor structure 10 shown in FIGS. 1-3, the TMBS of the trench semiconductor structure 10 shown in FIG. 5 only occupies a portion of the mesa surface between the first trench structure 21 and the second trench structure 22, and thus the leakage of the TMBS is reduced and the driving voltage is increased. At the same time, the channel space of the SGT MOSFET is increased, and thus the on-resistance (Ron) of the SGT MOSFET is reduced.

In some embodiments, when the first doped region 131 of the trench semiconductor structure 10 shown in FIGS. 1-3 and the trench semiconductor structure 10 shown in FIG. 5 have substantially the same doping concentration, the driving voltage of the TMBS of the trench semiconductor structure 10 shown in FIGS. 1-3 may be 0.3V, and the driving voltage of the TMBS of the trench semiconductor structure 10 shown in FIG. 5 may be 0.35V.

A fifth doped region 133 may be provided. The fifth doped region 133 and the first doped region 131 may be located between the first trench structure 21 and the second trench structure 22, and serve as the doped body region of the trench semiconductor structure 10. The fifth doped region 133 may be located between the first doped region 131 and the second trench structure 22. In some embodiments, the fifth doped region 133 is disposed between the first surface 11A and the second surface 11B, adjacent to the second oxide layer 224, and separated from the second gate 223. At least a portion of the second oxide layer 224 is located between the second gate 223 and the fifth doped region 133. In some embodiments, the fifth doped region 133 is located in the epitaxial layer 112 and in contact with the second oxide layer 224. The fifth doped region 133 is located in the semiconductor material layer 11 and adjacent to the first surface 11A, where the fifth doped region 133 has the second conductivity type, and the first doped region 131 is located between the first trench structure 21 and the fifth doped region 133. That is, the first doped region 131 and the fifth doped region 133 are disposed next to each other between the first trench structure 21 and the second trench structure 22. The first doped region 131 may adjoin the fifth doped region 133. The first doped region 131 is in the first region R1. The fifth doped region 133 is the second region R2.

At least a portion of the epitaxial layer 112 is disposed between the fifth doped region 133 and the substrate 111. In some embodiments, the fifth doped region 133 has a conductivity type different from that of the epitaxial layer 112, for example, having a conductivity type of the second type. In some embodiments, the fifth doped region 133 has P-type, and the epitaxial layer 112 has N-type. The fifth doped region 133 includes a P-type dopant, and the P-type dopant may be, for example, boron, aluminum, gallium, indium, and so on. In some embodiments, the P-type dopant included in the fifth doped region 133 is boron. The doping concentration of the fifth doped region 133 is greater than the doping concentration of the epitaxial layer 112. In some embodiments, the doping concentration of the fifth doped region 133 is different from the doping concentration of the first doped region 131. In some embodiments, the doping concentration of the fifth doped region 133 is greater than the doping concentration of the first doped region 131, for example, but not limited to, the doping concentration of the fifth doped region 133 is one order of magnitude greater than the doping concentration of the first doped region 131. In some embodiments, the doping concentration of the fifth doped region 133 is substantially the same as the doping concentration of the second doped region 132.

The depth of the fifth doped region 133 may be less than the depth of the bottom surface 213b of the first gate 213. The depth of the fifth doped region 133 may be the same as or different from the depth of the first doped region 131. In some embodiments, the depth of the fifth doped region 133 is greater than the depth of the first doped region 131. The depth of the fifth doped region 133 is the same as or different from the depth of the second doped region 132. In some embodiments, the depth of the fifth doped region 133 is substantially the same as the depth of the second doped region 132.

The semiconductor material layer 11 may further include a sixth doped region 143. The fifth doped region 133 and the sixth doped region 143 are located in the second region R2 between the first trench structure 21 and the second trench structure 22. The sixth doped region 143 extends in the first direction X in a top view of the trench semiconductor structure 10. In some embodiments, the sixth doped region 143 is located between the first surface 11A and the fifth doped region 133, adjacent to the second oxide layer 224 and separated from the second gate 223. The sixth doped region 143 is located in the semiconductor material layer 11 adjacent to the first surface 11A and adjacent to the second trench structure 22. In some embodiments, the sixth doped region 143 is located in the epitaxial layer 112 and in contact with the second oxide layer 224. At least a portion of the second oxide layer 224 is located between the second gate 223 and the sixth doped region 143.

The sixth doped region 143 is disposed between the second trench structure 22 and the fifth doped region 133, and serves as the source of the trench semiconductor structure 10. In some embodiments, the sixth doped region 143 has the same conductivity type as the epitaxial layer 112, for example, the first conductivity type. In some embodiments, the sixth doped region 143 and the epitaxial layer 112 have N-type. The doping concentration of the sixth doped region 143 is greater than the doping concentration of the epitaxial layer 112. The depth of the sixth doped region 143 is less than the depth of the bottom surface 213b of the first gate 213. The depth of the sixth doped region 143 is less than the depth of the fifth doped region 133. The shielding metal layer 181 contacts the fifth doped region 133 and the sixth doped region 143.

In some embodiments, the TMBS of the trench semiconductor structure 10 in FIG. 5 is located in the first region, and the first electrode 210, the first doped region 131 and the first conductive plug 171 form the TMBS in the first region R1. The second gate 223, the second electrode 220 (i.e., the fourth portion 222), the fifth doped region 133, the sixth doped region 143 and the second conductive plug 172 form the SGT MOSFT in the second region R2. In some embodiments, by adjusting the relative doping concentrations of the fifth doped region 133 and the sixth doped region 143 such that the sixth doped region 143 has a relatively high doping concentration, the current of the SGT MOSFT does not flow from the sixth doped region 143 to the second conductive plug 172.

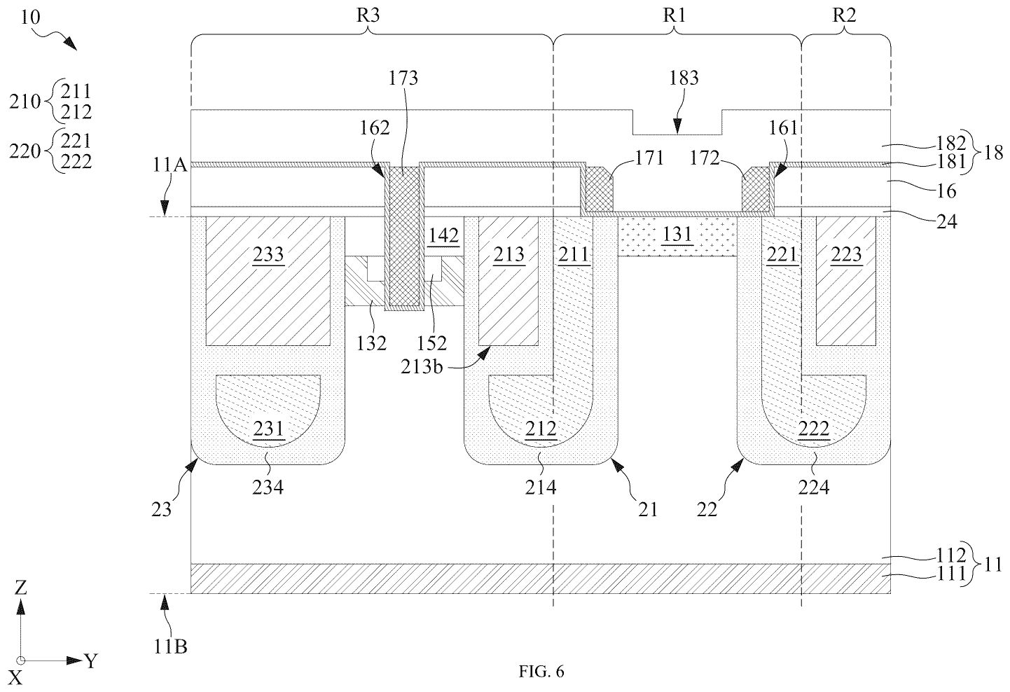

FIG. 6 is a cross-sectional view of another example of the trench semiconductor structure 10 according to some embodiments of the present disclosure. In some embodiments, referring to FIG. 6, the shielding metal layer 181 and the third conductive plug 173 in the second groove 162 may extend through the heavily doped region 152 and the second doped region 132. The heavily doped region 152 surrounds at least a portion of the shielding metal layer 181 and at least a portion of the third conductive plug 173. The bottoms of the shielding metal layer 181 and the third conductive plug 173 are located in the epitaxial layer 112, and the bottoms of the shielding metal layer 181 and the third conductive plug 173 contact the epitaxial layer 112 having the first conductivity type, forming a Schottky contact area. Compared with the trench semiconductor structure 10 shown in FIGS. 1-3, the Schottky contact area of the third region R3 of the trench semiconductor structure 10 shown in FIG. 6 is increased, thereby reducing the turn on voltage and increasing the possibility of reverse leakage.

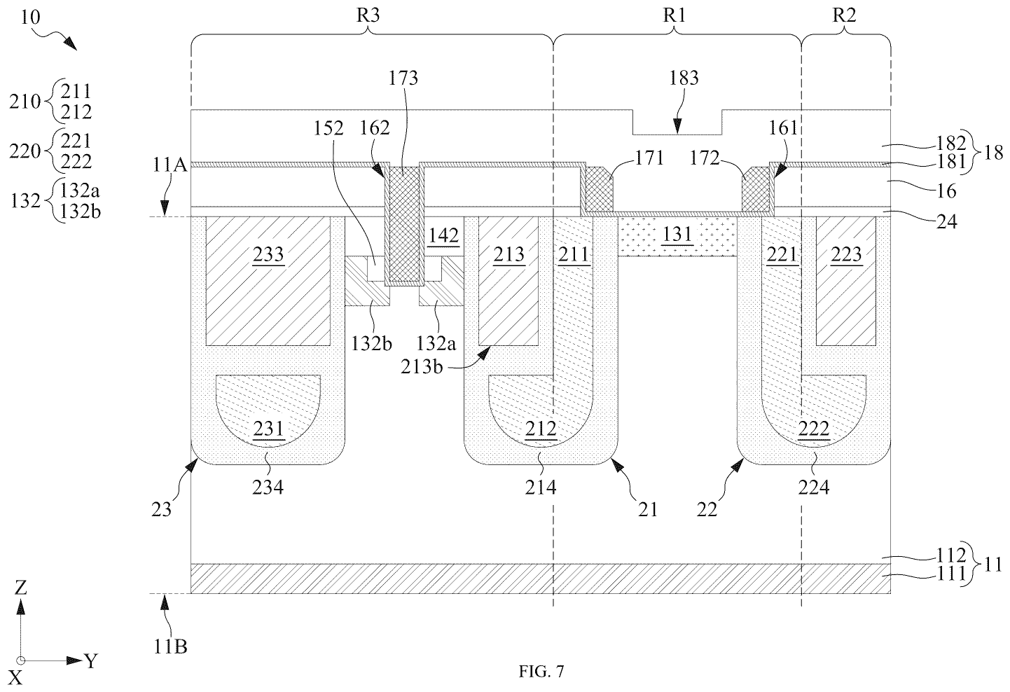

FIG. 7 is a cross-sectional view of another example of the trench semiconductor structure 10 according to some embodiments of the present disclosure. In some embodiments, referring to FIG. 7, the shielding metal layer 181 and the third conductive plug 173 in the second groove 162 may extend through the heavily doped region 152, and the heavily doped region 152 surrounds at least a portion of the shielding metal layer 181 and at least a portion of the third conductive plug 173. The second doped region 132 surrounds at least a portion of the sidewalls of the shielding metal layer 181 (i.e., the portion of the shielding metal layer 181 covering the sidewalls of the second groove 162) and at least a portion of the sidewalls of the third conductive plug 173, the bottoms of the shielding metal layer 181 and the third conductive plug 173 are located in the epitaxial layer 112, and the bottom of the third conductive plug 173 contacts the epitaxial layer 112 having the first conductivity type, forming a Schottky contact area. Compared with the trench semiconductor structure 10 shown in FIGS. 1-3, the Schottky contact area of the third region R3 of the trench semiconductor structure 10 shown in FIG. 7 is increased, thereby reducing the turn on voltage and increasing the possibility of leakage.

In some embodiments, the second doped region 132 includes a first sub-region 132a and a second sub-region 132b separated from each other. The first sub-region 132a may contact the first trench structure 21 and the shielding metal layer 181, the second sub-region 132b may contact the second trench structure 22 and the shielding metal layer 181, and the third conductive plug 173 is located between the first sub-region 132a and the second sub-region 132b separated from each other. The depth of the bottom of the first sub-region 132a and the depth of the bottom of the second sub-region 132b are greater than the depth of the bottom of the third conductive plug 173. The depth of the bottom of the third conductive plug 173 of the trench semiconductor structure 10 shown in FIG. 7 is less than the depth of the bottom of the second doped region 132, and by use of the second doped region 132 including the first sub-region 132a and the second sub-region 132b separated from each other, the bottoms of the shielding metal layer 181 and the third conductive plug 173 contact the epitaxial layer 112, thereby forming a Schottky contact area. Comparing the trench semiconductor structures 10 shown in FIG. 6 and FIG. 7, by utilizing different depths of the bottoms of the shielding metal layer 181 and the third conductive plug 173, different Schottky contact areas may be formed in the third region R3. The Schottky contact area affects the turn on voltage and reverse leakage, and the depth of the bottom of the third conductive plug 173 can be adjusted according to the required properties of the trench semiconductor structure 10.

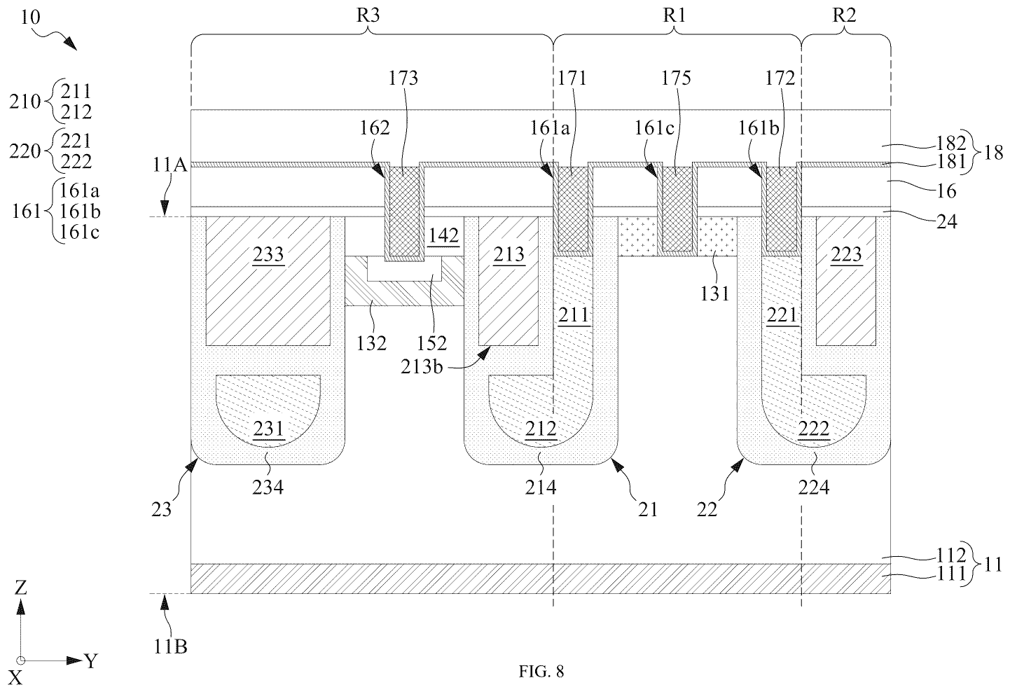

FIG. 8 is a cross-sectional view of another example of the trench semiconductor structure 10 according to certain embodiments of the present disclosure. In some embodiments, the first groove 161 includes a block 161a, a block 161b, and a block 161c, and the shielding metal layer 181 is conformally located in the block 161a, the block 161b, and the block 161c. Each of the block 161a, block 161b and block 161c is a groove, and the shielding metal layer 181 is disposed on and covers the sidewalls and the bottom of the groove. The first conductive plug 171 and the second conductive plug 172 are respectively located in the block 161a and the block 161b. A fifth conductive plug 175 is located in the block 161c. The metal layer 182 is located on the first conductive plug 171, the second conductive plug 172, and the fifth conductive plug 175. The shielding metal layer 181 surrounds the first conductive plug 171, the second conductive plug 172 and the fifth conductive plug 175. The fifth conductive plug 175 is electrically connected to the shielding metal layer 181, the metal layer 182 and the first doped region 131. In some embodiments, the first conductive plug 171, the second conductive plug 172 and the fifth conductive plug 175 extend through the interlayer dielectric layer 16 and the fourth oxide layer 24, respectively. The fifth conductive plug 175 extends from above the first surface 11A of the semiconductor material layer 11 towards the second surface 11B along the vertical direction Z.

When the first groove 161 includes the independent blocks 161a, 161b, and 161c, instead of an integral groove, the metal layer 182 does not have the recess 183.

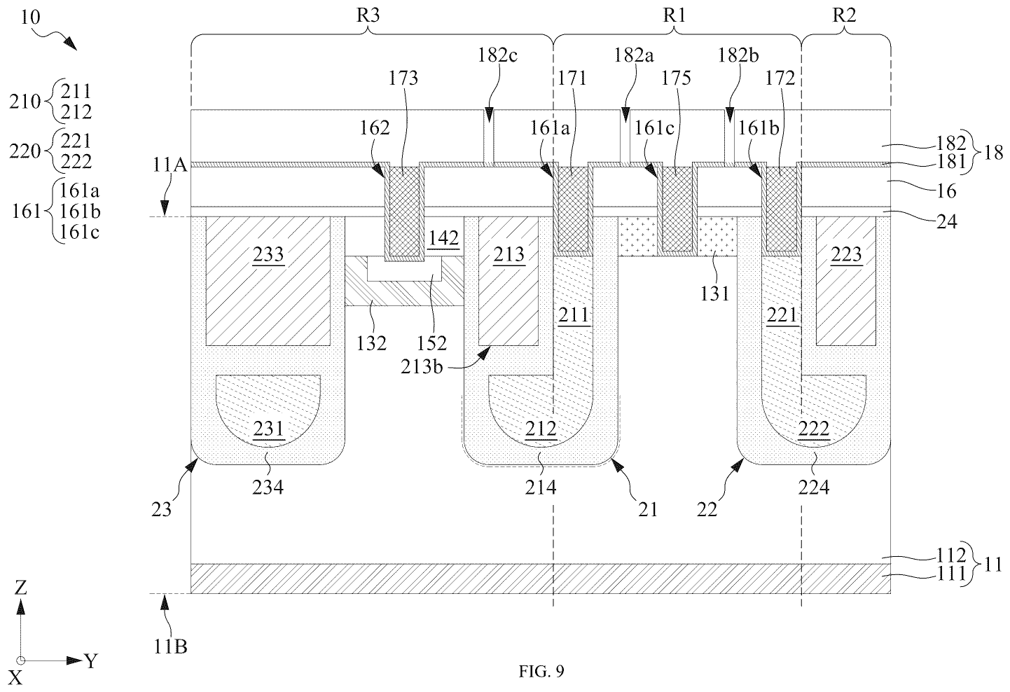

FIG. 9 is a cross-sectional view of another example of the trench semiconductor structure 10 according to some embodiments of the present disclosure. In some embodiments, openings 182a, 182b, and 182c may be provided extending through the conductive material layer 18. The openings 182a, 182b, and 182c penetrate the shielding metal layer 181 and the metal layer 182 to expose portions of the interlayer dielectric layer 16 from the openings 182a, 182b, and 182c. In some embodiments, the openings 182a and 182b are disposed above the first groove 161, and the opening 182c is disposed above the first trench structure 21. In some embodiments, the metal layer 182 between the openings 182a and 182b, and the metal layer 182 on the third conductive plug 173 are used respectively as sources. The metal layer 182 between the openings 182a and 182c and the metal layer 182 on the second conductive plug 172 may be respectively used as the gates, and the source or floating electrode. In some embodiments, when the metal layer 182 between the opening 182a and the opening 182c serves as the gate and is electrically connected to the first conductive plug 171, positive charges are accumulated on the first electrode 210, and electrons are adsorbed to the interface between the bottom of the first trench structure 21 and the epitaxial layer 112 (as shown by the dotted line at the bottom of the first trench structure 21), causing the on-resistance of the SGT MOSFET to decrease and the capacitance from the drain to the gate to increase, which configuration is suitable to be applied in the trench semiconductor structure 10 with a lower switching speed.

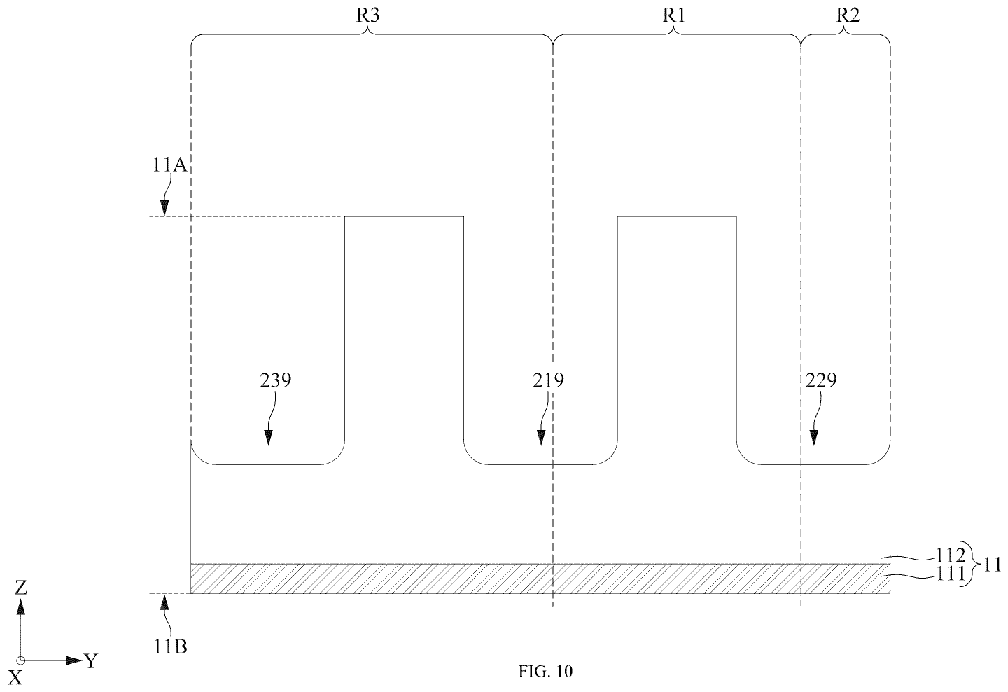

FIG. 10 to FIG. 34 are diagrams illustrating a trench semiconductor structure in one or more stages of a manufacturing method of the trench semiconductor structure according to some embodiments of the present disclosure. FIG. 10 to FIG. 34 show cross-sectional views and top views of the trench semiconductor structure. At least some of these figures have been simplified to facilitate a better understanding of aspects of the present disclosure.

Referring to FIG. 10, a semiconductor material layer 11 may include a substrate 111 and an epitaxial layer 112 located on the substrate 111. The manufacturing method includes performing epitaxial growth on the substrate 111 to form the epitaxial layer 112. The epitaxial layer 112 has a first surface 11A of the semiconductor material layer 11, the substrate 111 has a second surface 11B of the semiconductor material layer 11, and the first surface 11A is opposite to the second surface 11B. In some embodiments, ion implantation may be performed simultaneously with the epitaxial growth, and ions with N-type electrical properties are implanted to form the epitaxial layer 112 of N-type.

A first patterned shielding layer (not shown) may be formed on the epitaxial layer 112 to define positions of a first trench 219, a second trench 229 and a third trench 239 as shown in FIG. 10. An etching process (e.g., a plasma dry etching process) may be performed on the epitaxial layer 112 through the first patterned shielding layer to form the first trench 219, the second trench 229 and the third trench 239 at intervals. An etching process removes portions of the epitaxial layer 112 from the first surface 11A and stops in the epitaxial layer 112. According to the positions defined by the first patterned shielding layer, the first trench 219, the second trench 229 and the third trench 239 are formed at intervals in the semiconductor material layer 11 along the first direction X (in the top view) and extend from the first surface 11A towards the second surface 11B opposite to the first surface 11A. Part of the first trench 219 and part of the second trench 229 may be formed in a first region R1 of the semiconductor material layer 11, part of the second trench 229 may be formed in a second region R2 of the semiconductor material layer 11, and the third trench 239 may be formed in a third region R3 of the semiconductor material layer 11. The first region R1 is located between the second region R2 and the third region R3.

In some embodiments, the first groove 219, the second groove 229 and the third groove 239 may have vertical sidewalls along the direction Z. The first groove 219, the second groove 229 and the third groove 239 may have arc-shaped bottom surfaces. The first groove 219, the second groove 229 and the third groove 239 may be in other shapes, e.g., may be circular, elliptical, rectangular or polygonal. In some embodiments, the first groove 219, the second groove 229 and the third groove 239 have the same width. In some embodiments, the first groove 219, the second groove 229 and the third groove 239 have the same depth.

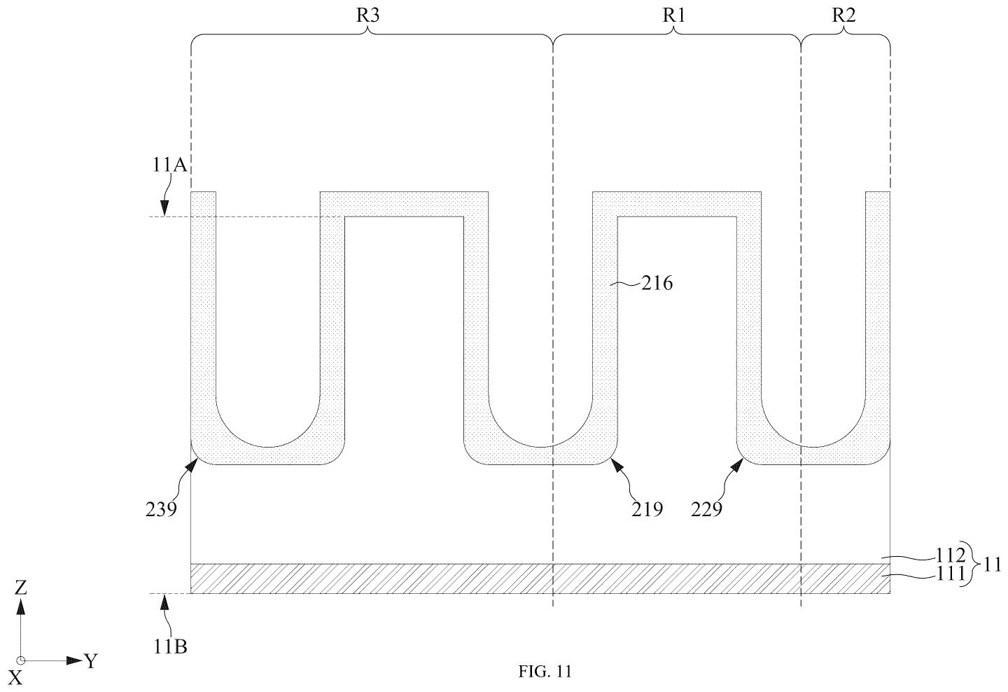

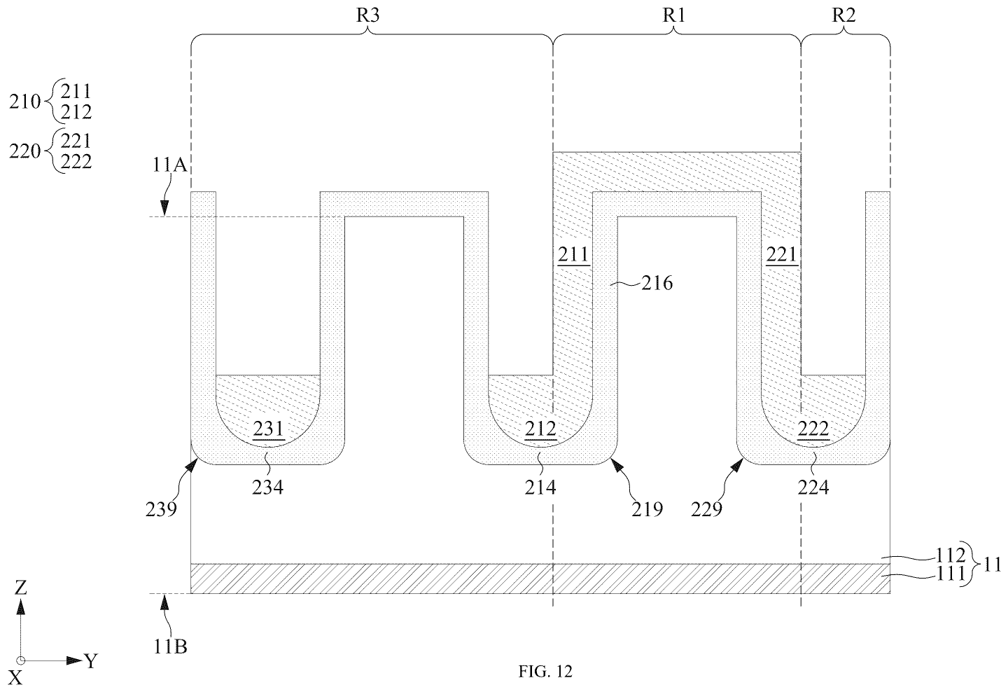

Referring to FIG. 11, the manufacturing method includes forming a first in-trench oxide layer 216 in the first trench 219, the second trench 229 and the third trench 239. In some embodiments, the first in-trench oxide layer 216 covers the first surface 11A. In some embodiments, the first in-trench oxide layer 216 may be formed by a thermal oxidation technology or other deposition processes, and the deposition processes may be, for example, atomic layer deposition (ALD), chemical vapor deposition (CVD), or other deposition methods. In some embodiments, the first in-trench oxide layer 216 may be conformally deposited on the inner side surfaces (for each trench, including the opposite sidewalls and the bottom extending between the sidewalls) of the first trench 219, the second trench 229 and the third trench 239. In some embodiments, the first in-trench oxide layer 216 may be filled into the first trench 219, the second trench 229, and the third trench 239 through a deposition process, such that the first in-trench oxide layer 216 forms at least one groove in each of the first trench 219, the second trench 229 and the third trench 239. In some embodiments, as shown in FIG. 12, the portion of the first in-trench oxide layer 216 in the first trench 219 is a first oxide layer 214, the portion of the first in-trench oxide layer 216 in the second trench 229 is a second oxide layer 224, and the portion of the first in-trench oxide layer 216 in the third trench 239 is a third oxide layer 234. The first oxide layer 214, the second oxide layer 224, and the third oxide layer 234 may be formed simultaneously.

Referring to FIG. 12, the manufacturing method includes forming a first electrode 210, a second electrode 220 and a third electrode 231 in the first trench 219, the second trench 229, and the third trench 239, respectively. The first electrode 210, the second electrode 220 and the third electrode 231 may be formed simultaneously. The first portion 211 and the second portion 212 of the first electrode 210 may be formed simultaneously. The third portion 221 and the fourth portion 222 of the second electrode 220 may be formed simultaneously.

In some embodiments, the first electrode 210 is disposed in the first trench 219 and on the top surface of the first oxide layer 214, the second electrode 220 is disposed in the second trench 229 and on the top surface of the second oxide layer 224, and the third electrode 231 is disposed in the third trench 239 and on the top surface of the third oxide layer 234. As shown, the first portion 211 of the first electrode 210 covers the first oxide layer 214 that is on one sidewall of the first trench 219 (the sidewall closer to the second trench 229). The second portion 212 of the first electrode 210 is disposed in the lower part of the cavity of the first trench 219 and on the first oxide layer 214. Similarly, the third portion 221 of the second electrode 220 covers the second oxide layer 224 that is on one sidewall of the second trench 229 (the sidewall closer to the first trench 219). The fourth portion 222 of the second electrode 220 is disposed in the lower part of the cavity of the second trench 229 and on the second oxide layer 224. The third electrode 231 is disposed in the lower part of the cavity of the third trench 239 and on the third oxide layer 234. The top surface of the second portion 212 of the first electrode 210, the top surface of the fourth portion 222 of the second electrode 220, and the top surface of the third electrode 231 may be coplanar. The first portion 211 of the first electrode 210 and the third portion 221 of the second electrode 220 may extend onto the first surface 11A and are connected to each other.

The first in-trench oxide layer 216 may surround the first electrode 210, the second electrode 220 and the third electrode 231. In some embodiments, the first electrode 210, the second electrode 220 and the third electrode 231 may be formed by physical vapor deposition (PVD), e.g., sputtering or spraying of a semiconductor material or electrode material. In some embodiments, the first electrode 210, the second electrode 220 and the third electrode 231 may be formed by electroplating or CVD of a semiconductor material or electrode material. In some embodiments, the semiconductor material or electrode material may cover the first in-trench oxide 216, and then an etching process may be performed to remove the semiconductor material or electrode material outside the first trench 219, the second trench 229 and the third trench 239 by methods such as dry etching to form the first electrode 210, the second electrode 220 and the third electrode 231. In some embodiments, the semiconductor material or electrode material includes polysilicon.

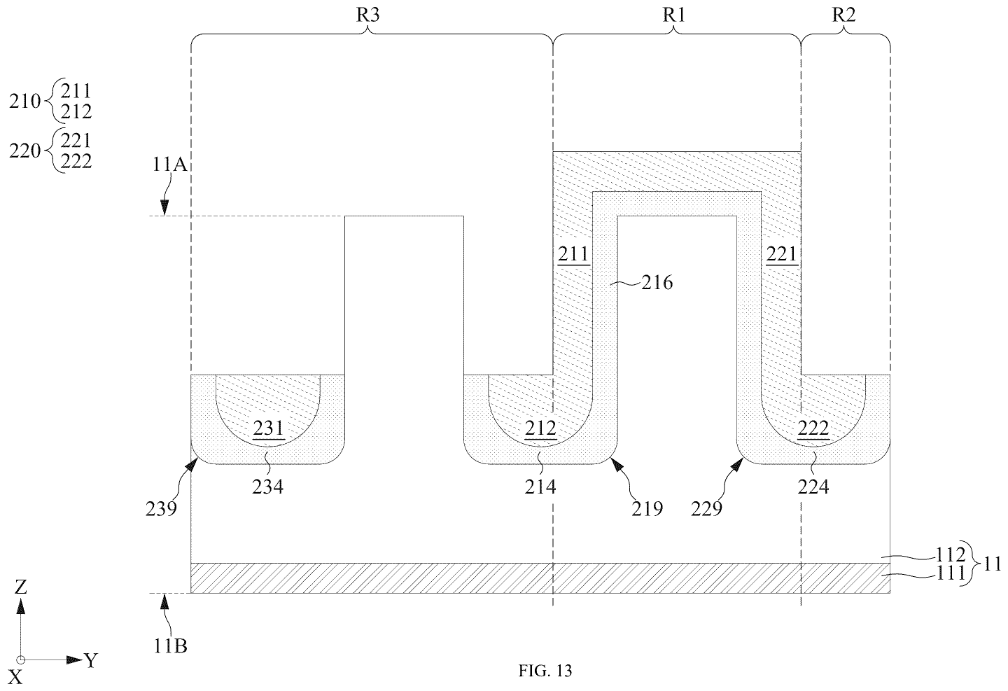

Referring to FIG. 13, the manufacturing method includes removing a portion of the first in-trench oxide layer 216 in the first trench 219, the second trench 229 and the third trench 239, so as to expose a portion of the inner side surfaces of the first trench 219 and the second trench 229, and a portion of the inner side surfaces of the third trench 239. In some embodiments, the manufacturing method includes removing the first in-trench oxide layer 216 in the first trench 219 that is not in contact with the first electrode 210, removing the first in-trench oxide layer 216 in the second trench 229 that is not in contact with the second electrode 220, and removing a portion of the first in-trench oxide layer 216 in the third trench 239 that is not in contact with the third electrode 231. In some embodiments, after removing the portions of the first in-trench oxide layer 216 in the first trench 219, the second trench 229 and the third trench 239, the first trench 219 includes the first electrode 210 and the first oxide layer 214 in contact with the first electrode 210, the second trench 229 includes the second electrode 220 and the second oxide layer 224 in contact with the second electrode 220, and the third trench 239 includes the third electrode 231 located at the bottom (or lower part) of the third trench 239 and the third oxide layer 234 surrounding the third electrode 231.

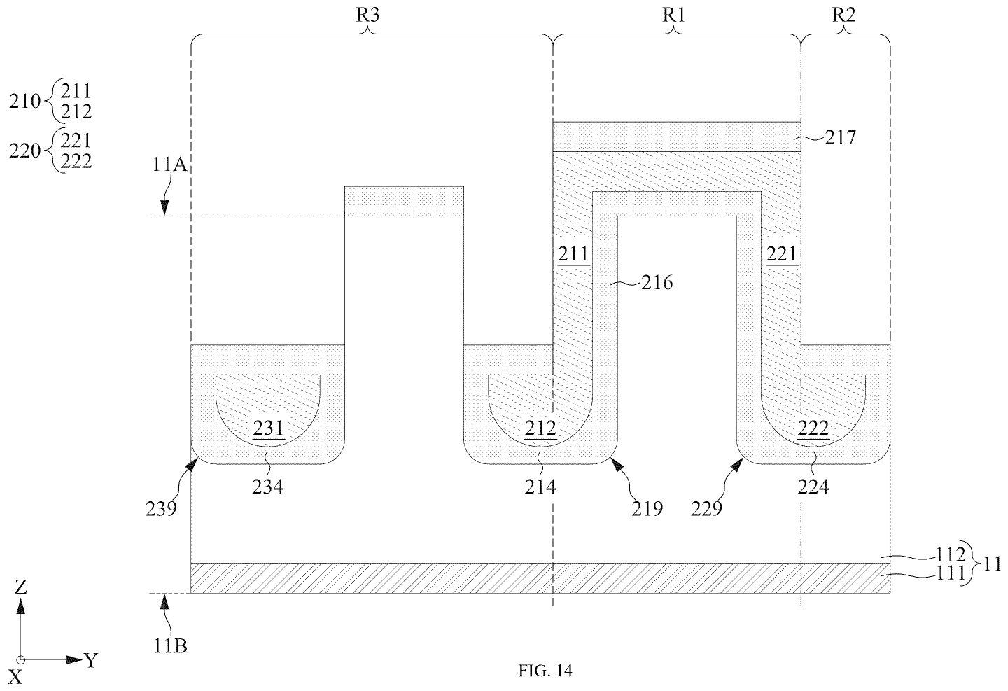

Referring to FIG. 14, the manufacturing method includes forming a second in-trench oxide layer 217 in the first trench 219, the second trench 229 and the third trench 239. In some embodiments, the second in-trench oxide layer 217 covers the first electrode 210, the second electrode 220, the third electrode 231, and the first surface 11A. In some embodiments, the second in-trench oxide layer 217 may be formed by a thermal oxidation technology or other deposition processes. In some embodiments, the second in-trench oxide layer 217 may be filled into the first trench 219, the second trench 229 and the third trench 239 by a deposition process, such that the second in-trench oxide layer 217 is conformally deposited on the first electrode 210 in the first trench 219, on the second electrode 220 in the second trench 229, and on the third electrode 231 in the third trench 239, respectively. In some embodiments, the second in-trench oxide layer 217 may be formed by an anisotropic deposition process. In some embodiments, the second in-trench oxide layer 217 may be used as a sacrificial structure and will be removed in a subsequent step so that surfaces exposed after removing the second in-trench oxide layer 217 have better quality, e.g., being smoother, which is conducive to forming other structures on the exposed surfaces.

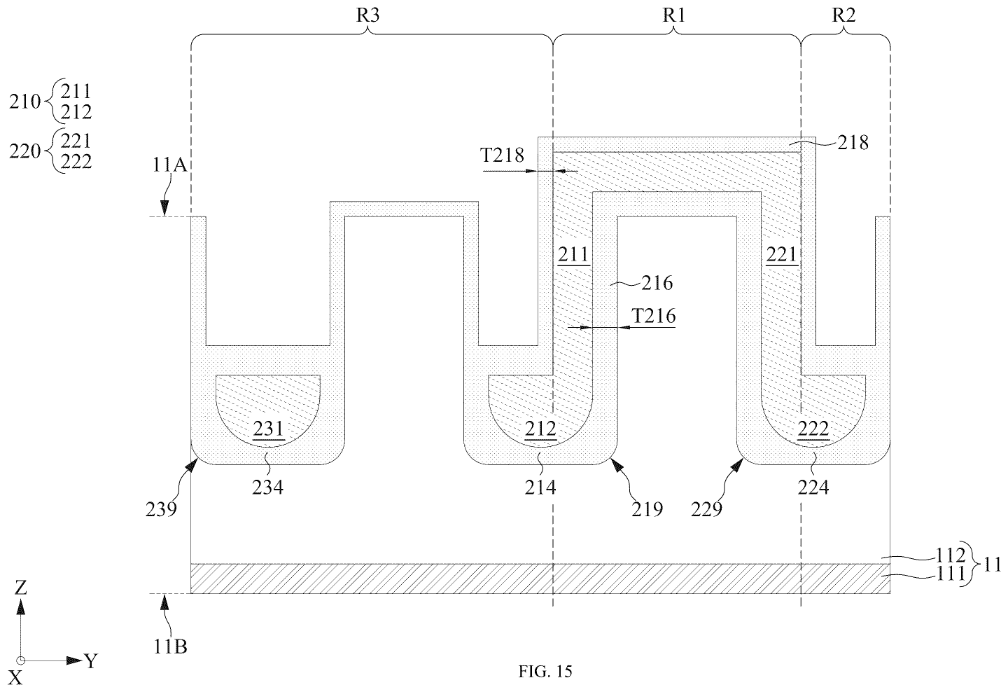

Referring to FIG. 15, the manufacturing method includes removing the second in-trench oxide layer 217. The manufacturing method includes removing the second in-trench oxide layer 217 located in the first region R1, the second region R2 and the third region R3, that is, removing the second in-trench oxide layer 217 that covers the first electrode 210, the second electrode 220 and the first surface 11A, to expose part of the inner side surfaces (including the opposite sidewalls) of the first trench 219, the second trench 229 and the third trench 239, and expose the connected first electrode 210 and the second electrode 220 (the trench semiconductor structure 10 after the second in-trench oxide layer 217 is removed and thus is not shown). The second in-trench oxide layer 217 may be removed by etching. The epitaxial layer 112 exposed by removing the second in-trench oxide layer 217 has an even and flat surface. In some embodiments, the stage shown in FIG. 14 may be omitted.

The manufacturing method may include forming a third in-trench oxide layer 218 on the epitaxial layer 112 exposed in the third region R3, and on the top surfaces and sidewalls of the first electrode 210 and the second electrode 220 located in the first region R1 and the second region R2. The third in-trench oxide layer 218 is formed in the first region R1, the second region R2 and the third region R3, and at least part of the third in-trench oxide layer 218 is located in the first trench 219, the second trench 229 and the third trench 239. In some embodiments, the third in-trench oxide layer 218 covers the first surface 11A. In some embodiments, the third in-trench oxide layer 218 may be formed by a thermal oxidation technology or other deposition processes. In some embodiments, the third in-trench oxide layer 218 may be conformally deposited on the inner side surfaces (including the opposite sidewalls) of the first trench 219, the second trench 229 and the third trench 239 and the top surfaces and sidewalls of the first electrode 210 and the second electrode 220.

In some embodiments, the third in-trench inner oxide layer 218 may be filled into the first trench 219, the second trench 229, and the third trench 239 through a deposition process, such that the third in-trench inner oxide layer 218 covers and surrounds the first electrode 210 and the second electrode 220, and forms a groove with the first oxide layer 214 in the first trench 219, and forms a groove with the second oxide layer 224 in the second trench 229. In some embodiments, the thickness T218 of the third in-trench oxide layer 218 is less than the thickness T216 of the first in-trench oxide layer 216. The first in-trench oxide layer 216, the second in-trench oxide layer 217 and the third in-trench oxide layer 218 may be the same material.

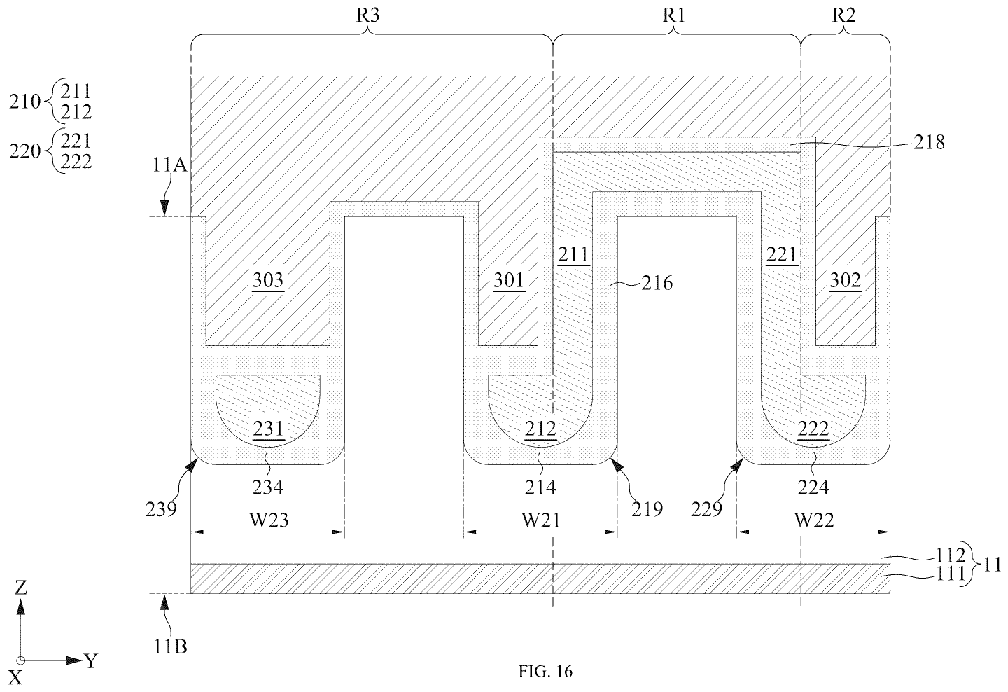

Referring to FIG. 16, the manufacturing method includes forming a first semiconductor material 301, a second semiconductor material 302, and a third semiconductor material 303 in the first trench 219, the second trench 229, and the third trench 239, respectively. In some embodiments, the first semiconductor material 301 is disposed in the first trench 219 and on the top surface of the third in-trench oxide layer 218 in the first trench 219, the second semiconductor material 302 is disposed in the second trench 229 and on the top surface of the third in-trench oxide layer 218 in the second trench 229, and the third semiconductor material 303 is disposed in the third trench 239 and on the top surface of third in-trench oxide layer 218 in the third trench 239.

The third in-trench oxide layer 218 may surround at least part of the first semiconductor material 301, the second semiconductor material 302, and the third semiconductor material 303. In some embodiments, the first semiconductor material 301, the second semiconductor material 302, and the third semiconductor material 303 may be formed by physical vapor deposition (PVD), e.g., by sputtering or spraying semiconductor materials. In some embodiments, the first semiconductor material 301, the second semiconductor material 302, and the third semiconductor material 303 may be formed by electroplating or CVD of semiconductor materials. In some embodiments, the first semiconductor material 301, the second semiconductor material 302, and the third semiconductor material 303 include polysilicon. In some embodiments, the first semiconductor material 301, the second semiconductor material 302, and the third semiconductor material 303 cover the third in-trench oxide layer 218.

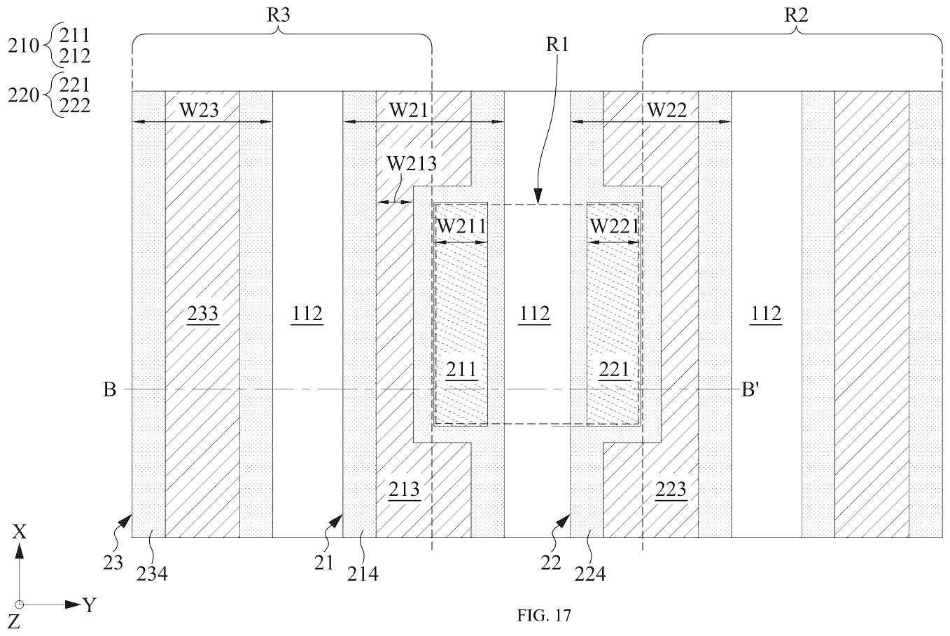

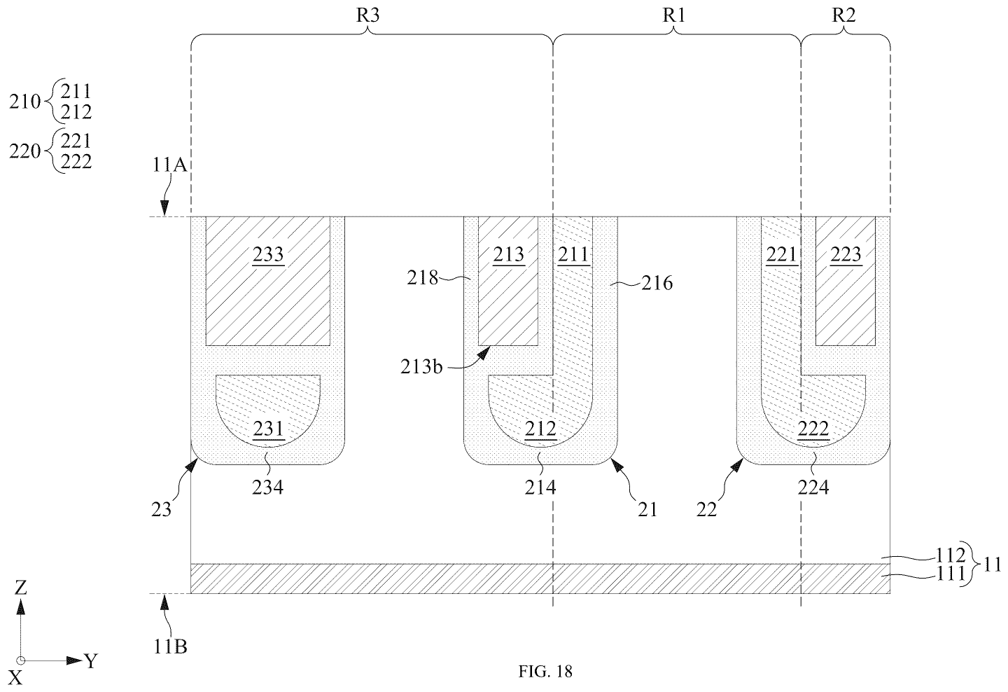

FIG. 17 is a top view of an example of a trench semiconductor structure in a stage of a manufacturing method of the trench semiconductor structure according to some embodiments of the present disclosure. FIG. 18 is a cross-sectional view of the trench semiconductor structure taken along a line B-B′ at the stage shown in FIG. 17 in the manufacturing method of the trench semiconductor structure according to some embodiments of the present disclosure. FIG. 17 and FIG. 18 are based on the trench semiconductor structure described with respect to FIG. 16, and show the trench semiconductor structure with further manufacturing processes performed subsequently, as discussed in the following.

Referring to FIG. 17 and FIG. 18, the manufacturing method includes removing a portion of the first semiconductor material 301 and a portion of the first electrode 210 that are above the first surface 11A of the semiconductor material layer 11, such that a portion of the first semiconductor material 301 located in the first trench 219 forms the first gate 213. The manufacturing method may further include removing a portion of the second semiconductor material 302 and a portion of the second electrode 220 that are above the first surface 11A of the semiconductor material layer 11, such that a portion of the second semiconductor material 302 located in the second trench 229 forms the second gate 223. The manufacturing method may also include removing a portion of the third semiconductor material 303 above the first surface 11A of the semiconductor material layer 11, such that a portion of the third semiconductor material 303 located in the third trench 239 forms the third gate 233. In addition, portions of the first in-trench oxide layer 216 and the third in-trench oxide layer 218 above the first surface 11A may also be removed, such that the first surface 11A in the first region R1 and the third region R3 is exposed. Part of the first semiconductor material 301, part of the second semiconductor material 302, part of the third semiconductor material 303, part of the first in-trench oxide layer 216, part of the third in-trench oxide layer 218, part of the first electrode 210 and part of the second electrode 220 may be polished by, for example, a chemical-mechanical polishing (CMP) process.

In some embodiments, the first gate 213, the second gate 223, and the third gate 233 are formed simultaneously. The first electrode 210 may be formed before forming the first gate 213. The second electrode 220 may be formed before forming the second gate 223. In some embodiments, after forming the first gate 213 in the first trench 219, the first electrode 210 including the first portion 211 and the second portion 212, the first gate 213 adjacent to the first portion 211, and the first oxide layer 214 surrounding and separating the first electrode 210 and the first gate 213, form the first trench structure 21. After forming the second gate 223 in the second trench 229, the second electrode 220 including the third portion 221 and the fourth portion 222, the second gate 223 adjacent to the third portion 221, and the second oxide layer 224 surrounding and separating the second electrode 220 and the second gate 223, form the second trench structure 22. In some embodiments, after forming the third gate 233 in the third trench 239, the third gate 233 is located over the third electrode 231. The third gate 233, the third electrode 231, and the third oxide layer 234 surrounding and separating the third gate 233 and the third electrode 231, form the third trench structure 23. In some embodiments, the first trench structure 21, the second trench structure 22, and the third trench structure 23 are formed simultaneously. In some embodiments, the top surface of the first trench structure 21, the top surface of the second trench structure 22, and the top surface of the third trench structure 23 are coplanar with the first surface 11A.

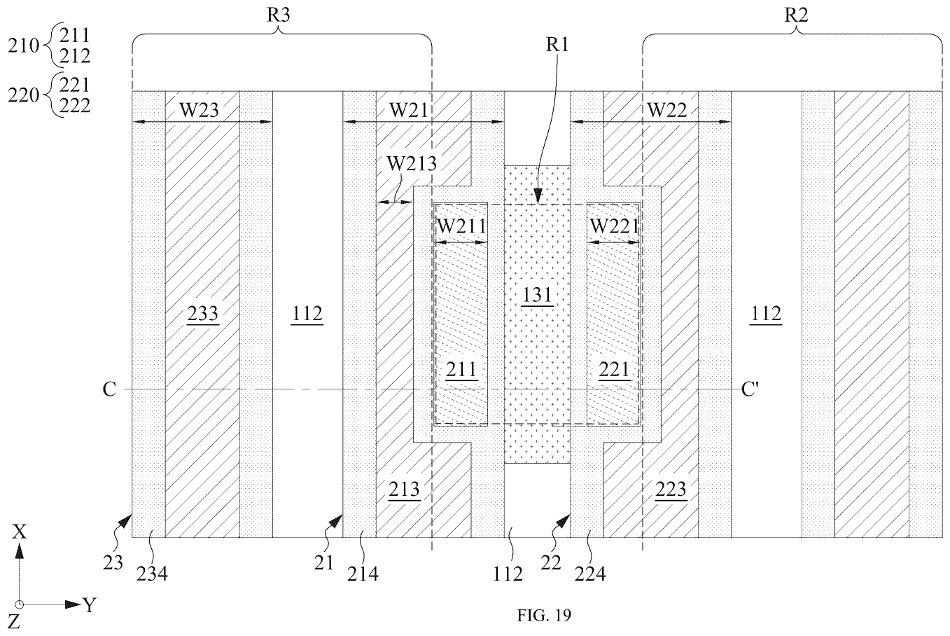

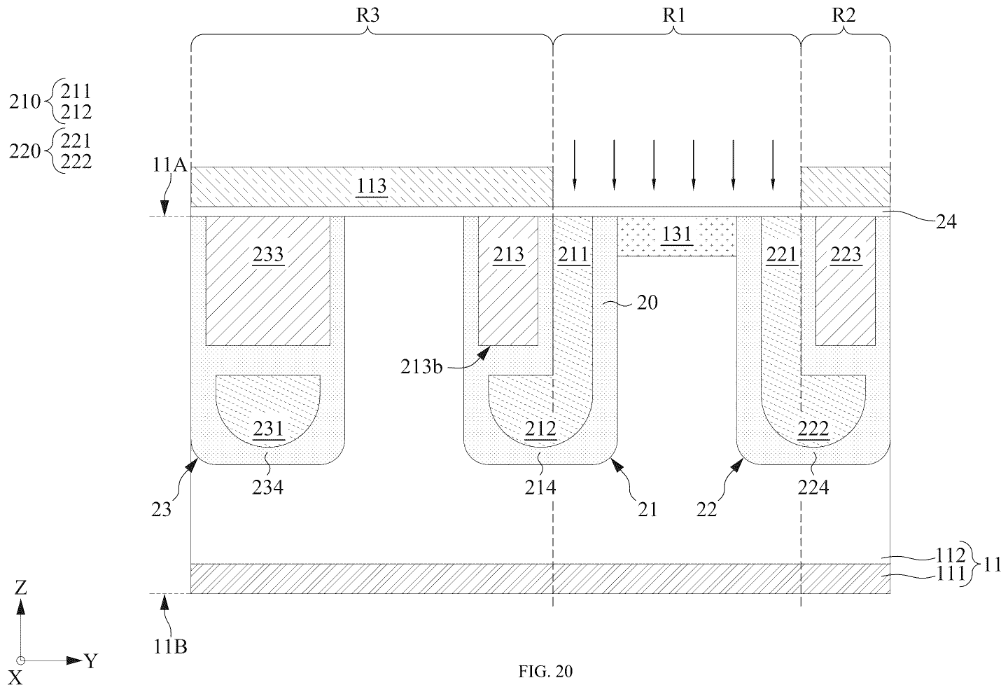

FIG. 19 is a top view of an example of a trench semiconductor structure in a stage of a manufacturing method of the trench semiconductor structure according to some embodiments of the present disclosure. FIG. 20 is a cross-sectional view of the trench semiconductor structure taken along a line C-C′ at the stage shown in FIG. 19 in the manufacturing method of the trench semiconductor structure according to some embodiments of the present disclosure. FIG. 19 and FIG. 20 are based on the trench semiconductor structure described with respect to FIGS. 18-19, and show the trench semiconductor structure with further manufacturing processes performed subsequently, as discussed in the following.

Referring to FIG. 19 and FIG. 20, the manufacturing method includes forming a fourth oxide layer 24 on the top surface of the first trench structure 21, the top surface of the second trench structure 22, the top surface of the third trench structure 23 and the first surface 11A. The fourth oxide layer 24 is in contact with the first surface 11A of the semiconductor material layer 11, the first trench structure 21, the second trench structure 22, and the third trench structure 23. In some embodiments, the fourth oxide layer 24 may be formed by a thermal oxidation technology or other deposition processes, such as ALD, CVD, or other deposition methods.

Referring to FIG. 20, the manufacturing method includes forming the first doped region 131 in the semiconductor material layer 11 between the first trench structure 21 and the second trench structure 22, and the first doped region 131 has a second conductivity type. The first doped region 131 may be formed in the epitaxial layer 112 by diffusion or ion implantation from the first surface 11A, and ions are implanted into the first surface 11A between the first trench structure 21 and the second trench structure 22 along the vertical direction Z. The first doped region 131 is formed in the first region R1, and the depth of the first doped region 131 is less than the depth of the first trench structure 21, the second trench structure 22, and the third trench structure 23. In other words, the bottom of the first doped region 131 is higher than the bottoms of the first trench structure 21, the second trench structure 22 and the third trench structure 23. In some embodiments, an annealing process is performed after the first doped region 131 is formed by the ion implantation process to diffuse the doping ions. In some embodiments, the doping ions are, for example, boron ions, aluminum ions, gallium ions, indium ions, and so on. In some embodiments, boron ions are implanted into the first doped region 131.

In some embodiments, a first patterned shielding layer 113 is formed on the fourth oxide layer 24 to define the position of the first doped region 131, and the conductivity type and depth of the first doped region 131 may be defined by adjusting the ions, energy and dose of the diffusion or ion implantation process. In some embodiments, the first patterned shielding layer 113 is formed by performing a photolithography process using a photomask having a corresponding pattern for forming the first doped region 131.

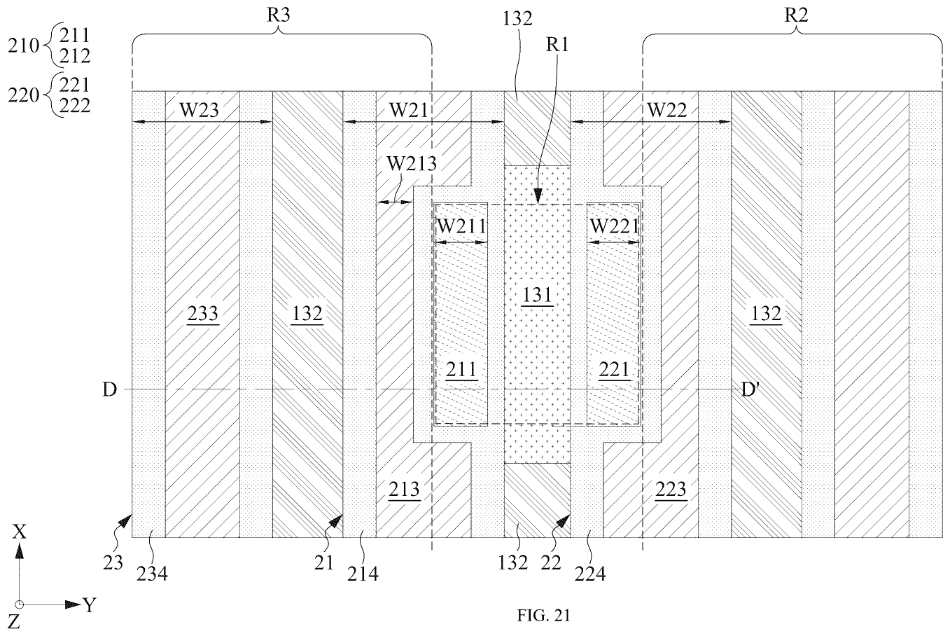

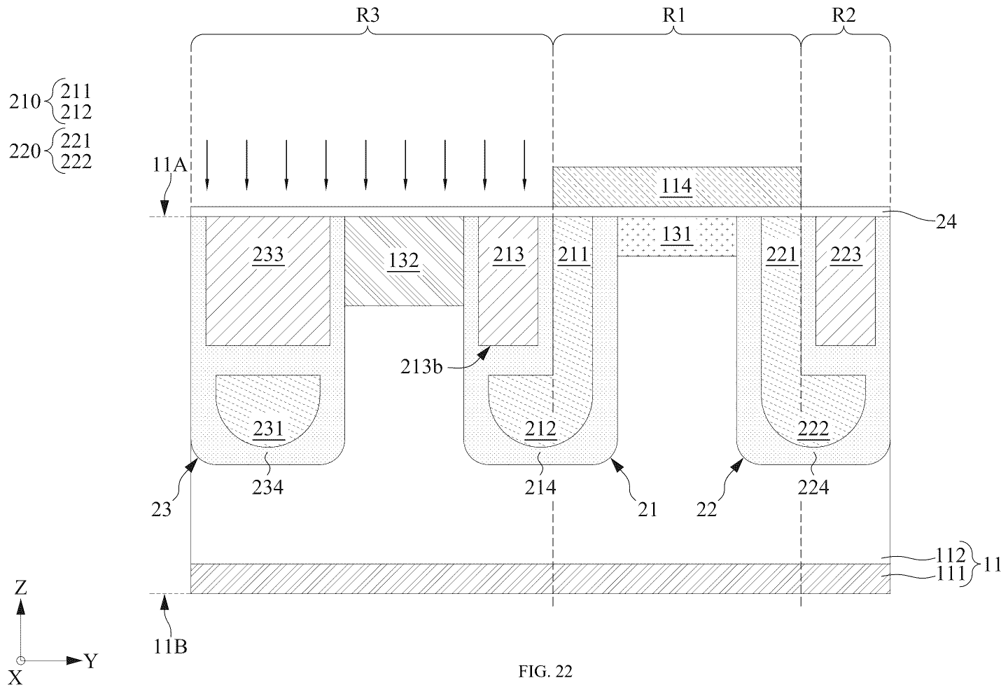

FIG. 21 is a top view of an example of a trench semiconductor structure in a stage of a manufacturing method of the trench semiconductor structure according to some embodiments of the present disclosure. FIG. 22 is a cross-sectional view of the trench semiconductor structure taken along a line D-D′ at the stage shown in FIG. 21 in the manufacturing method of the trench semiconductor structure according to some embodiments of the present disclosure. FIG. 21 and FIG. 22 are based on the trench semiconductor structure described with respect to FIGS. 19-20, and show the trench semiconductor structure with further manufacturing processes performed subsequently, as discussed in the following.

Referring to FIG. 21 and FIG. 22, the manufacturing method includes forming the second doped region 132 in the semiconductor material layer 11 between the second trench structure 22 and the third trench structure 23, and the second doped region 132 has a second conductivity type. The second doped region 132 may be formed in the epitaxial layer 112 by diffusion or ion implantation from the first surface 11A, and the ions are implanted into the first surface 11A along the vertical direction Z. The second doped region 132 may be formed in the second region R2 or the third region R3, and the depth of the second doped region 132 may be less than the depth of the first trench structure 21, the second trench structure 22 and the third trench structure 23. In other words, the bottom of the second doped region 132 is higher than the bottoms of the first trench structure 21, the second trench structure 22 and the third trench structure 23. In some embodiments, an annealing process is performed after the second doped region 132 is formed by the ion implantation process to diffuse the doping ions. In some embodiments, the doping ions are, for example, boron ions, aluminum ions, gallium ions, indium ions, and so on. In some embodiments, boron ions are implanted into the second doped region 132. The bottom of the second doped region 132 may be lower than that of the first doped region 131. That is, the depth of the second doped region 132 is greater than the depth of the first doped region 131.

In some embodiments, a second patterned shielding layer 114 is formed on the fourth oxide layer 24 to define the position of the second doped region 132 The conductivity type and depth of the second doped region 132 may be defined by adjusting the ions, energy and dose of the diffusion or ion implantation process of the second doped region 132. In some embodiments, the second patterned shielding layer 114 is formed by a photolithography process using a photomask having a corresponding pattern. The first doped region 131 and the second doped region 132 may be formed separately and have the same or different doping concentrations. In some embodiments, the first doped region 131 is formed before the second doped region 132 is formed. In some embodiments, the doping concentration of the second doped region 132 is greater than the doping concentration of the first doped region 131.

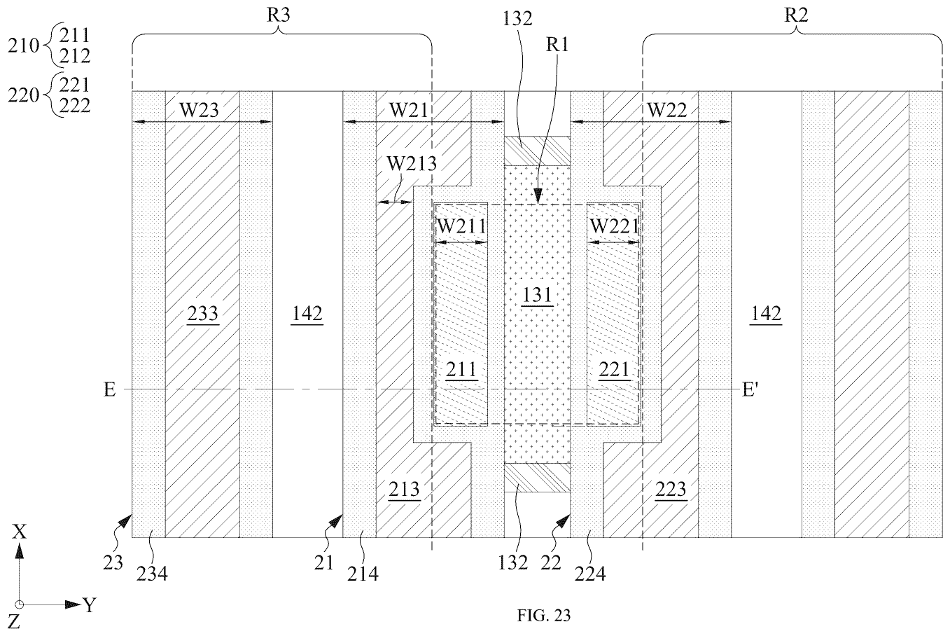

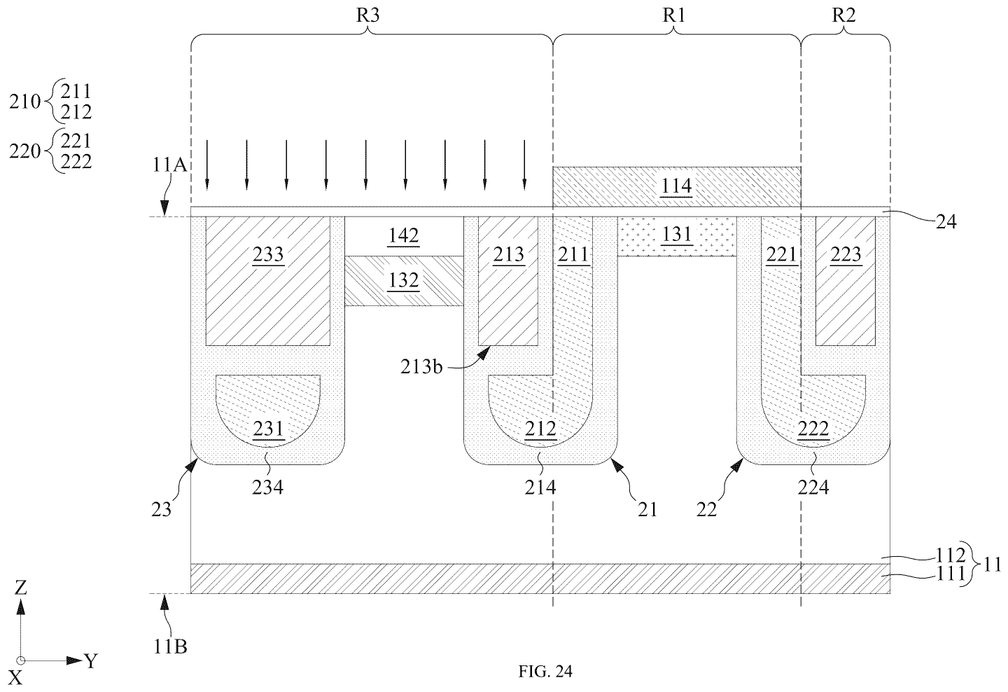

FIG. 23 is a top view of an example of a trench semiconductor structure in a stage of a manufacturing method of the trench semiconductor structure according to some embodiments of the present disclosure. FIG. 24 is a cross-sectional view of the trench semiconductor structure taken along a line E-E′ at the stage shown in FIG. 23 in the manufacturing method of the trench semiconductor structure according to some embodiments of the present disclosure. FIG. 23 and FIG. 24 are based the trench semiconductor structure described with respect to FIGS. 21-22, and show the trench semiconductor structure with further manufacturing processes performed subsequently, as discussed in the following.

Referring to FIG. 23 and FIG. 24, the manufacturing method includes forming the third doped region 142 in the second doped region 132 adjacent to the first surface 11A of the semiconductor material layer 11, where the third doped region 142 is a heavily doped region of the first conductivity type. The third doped region 142 may be formed between the second doped region 132 and the fourth oxide layer 24.

The third doped region 142 may be formed in the epitaxial layer 112 by diffusion or ion implantation from the first surface 11A, and ions are implanted into the first surface 11A along the vertical direction Z. The third doped region 142 may be formed in the second region R2 or the third region R3, and the depth of the third doped region 142 may be less than the depth of the second doped region 132. In some embodiments, an annealing process is performed after the third doped region 142 is formed by the ion implantation process to diffuse the doped ions. In some embodiments, the first doped region 131 is formed before the third doped region 142 is formed.

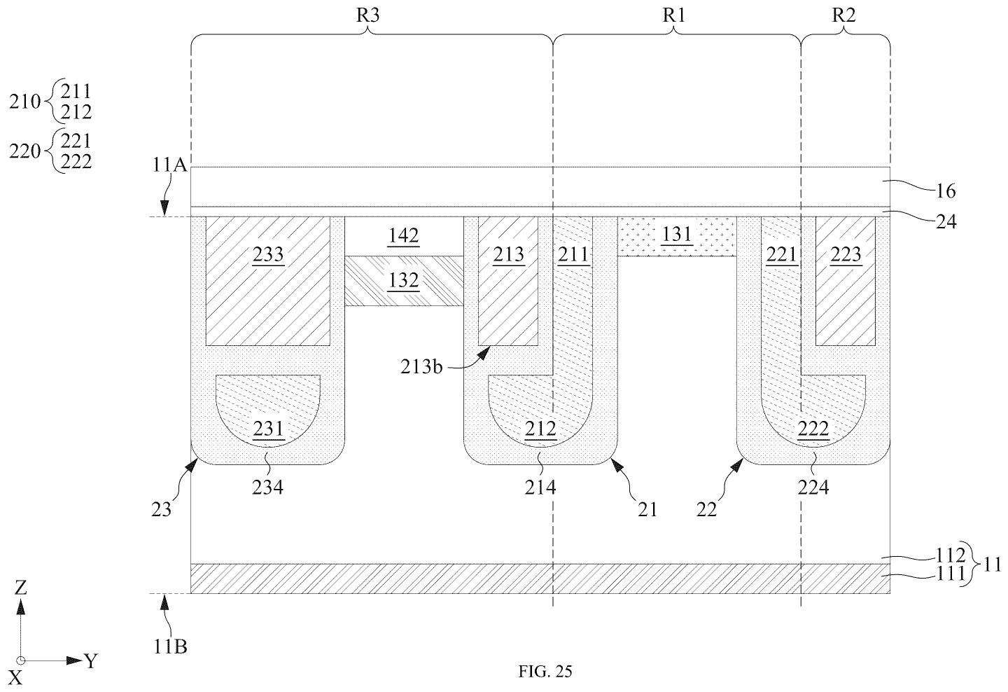

Referring to FIG. 25, based on the trench semiconductor structure in FIG. 24, the manufacturing method includes forming the interlayer dielectric layer 16 over the first surface 11A of the semiconductor material layer 11. The manufacturing method includes forming the interlayer dielectric layer 16 on the fourth oxide layer 24. The interlayer dielectric layer 16 covers the first trench structure 21, the second trench structure 22, the third trench structure 23, the first doped region 131, and the third doped region 142. The interlayer dielectric layer 16 may be formed by a thermal oxidation technology or other deposition processes.

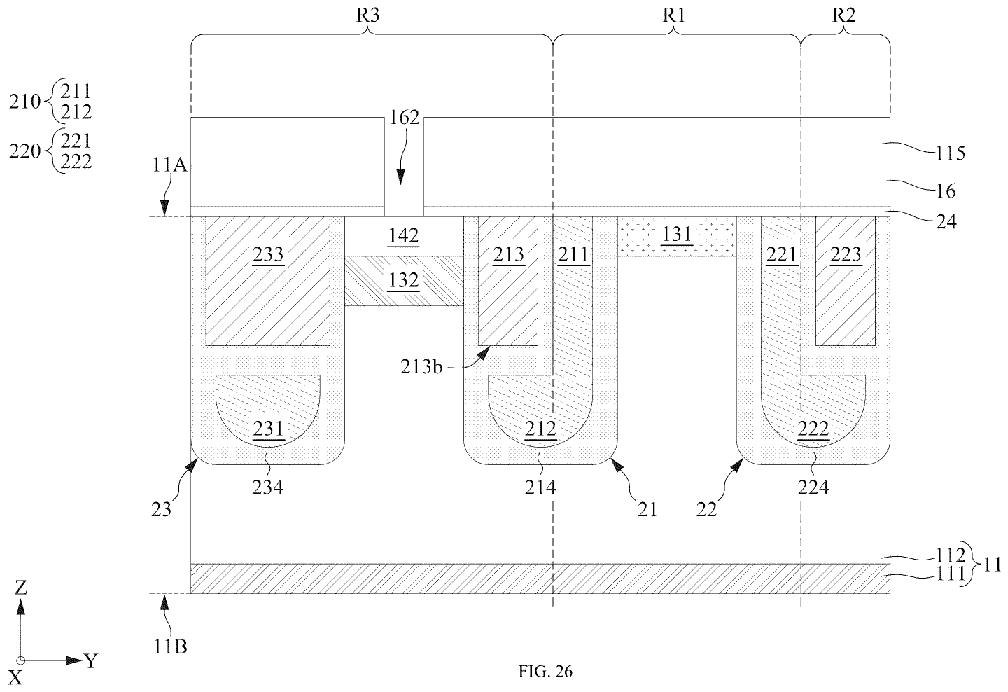

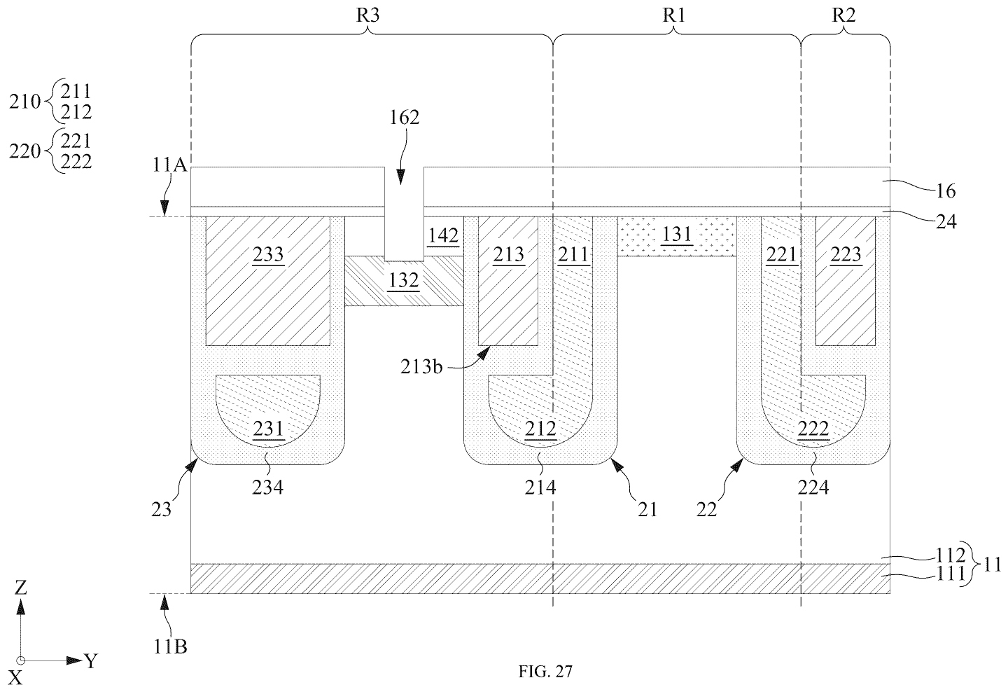

Referring to FIG. 26 and FIG. 27, the manufacturing method further includes partially removing the interlayer dielectric layer 16 and the fourth oxide layer 24, and partially removing the epitaxial layer 112 to form the second groove/opening 162. The second groove/opening 162 may be formed by one or more etching processes. The second groove/opening 162 is located between the first trench structure 21 and the third trench structure 23, extends through the third doped region 142 and stops in the second doped region 132.

In some embodiments, referring to FIG. 26, a third patterned shielding layer 115 may be formed on the interlayer dielectric layer 16 to define the position of the second groove/opening 162. The interlayer dielectric layer 16 and the fourth oxide layer 24 in the third region R3 are partially removed by adjusting the position of the third patterned shielding layer 115. In some embodiments, the third patterned shielding layer 115 is formed by performing a photolithography process using a photomask having a corresponding pattern. Referring to FIG. 27, after partially removing the interlayer dielectric layer 16 and the fourth oxide layer 24, the third patterned shielding layer 115 is removed, and the interlayer dielectric layer 16 and the fourth oxide layer 24 are used as a mask to further partially remove the epitaxial layer 112 to form the second groove/opening 162.

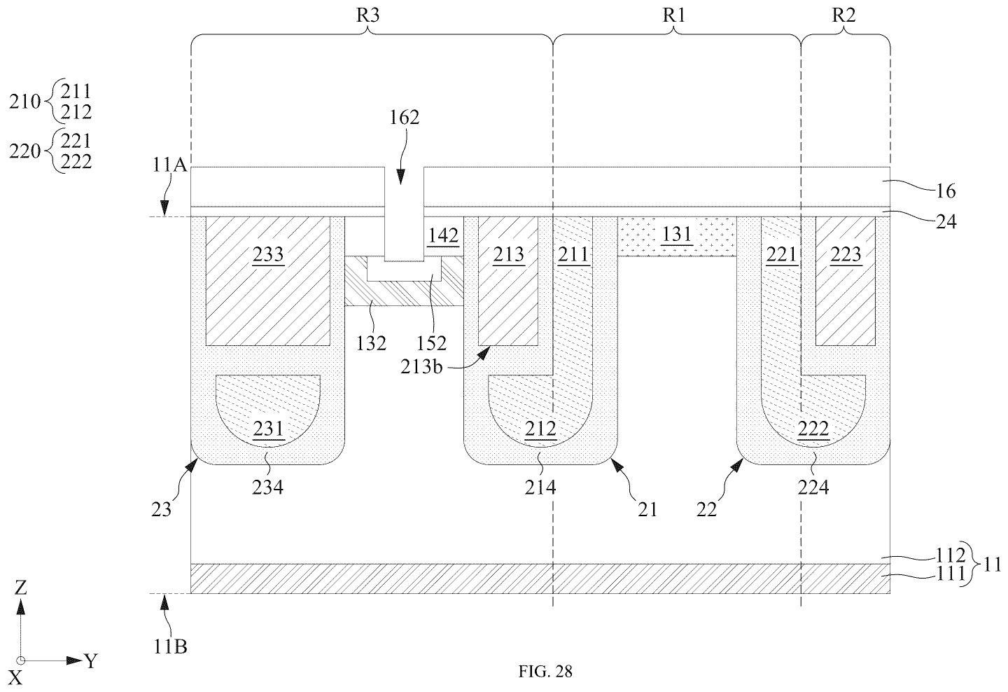

Referring to FIG. 28, the manufacturing method further includes performing an ion implantation process on the epitaxial layer 112 through the second groove/opening 162 to form the heavily doped region 152 in the third region R3. Ions are implanted into the epitaxial layer 112 at the bottom of the second groove/opening 162 along the vertical direction Z. The heavily doped region 152 is formed in the epitaxial layer 112 adjacent to the bottom of the second groove/opening 162. In some embodiments, an annealing process is performed after the ion implantation process to form the heavily doped region 152 as shown in FIG. 28.

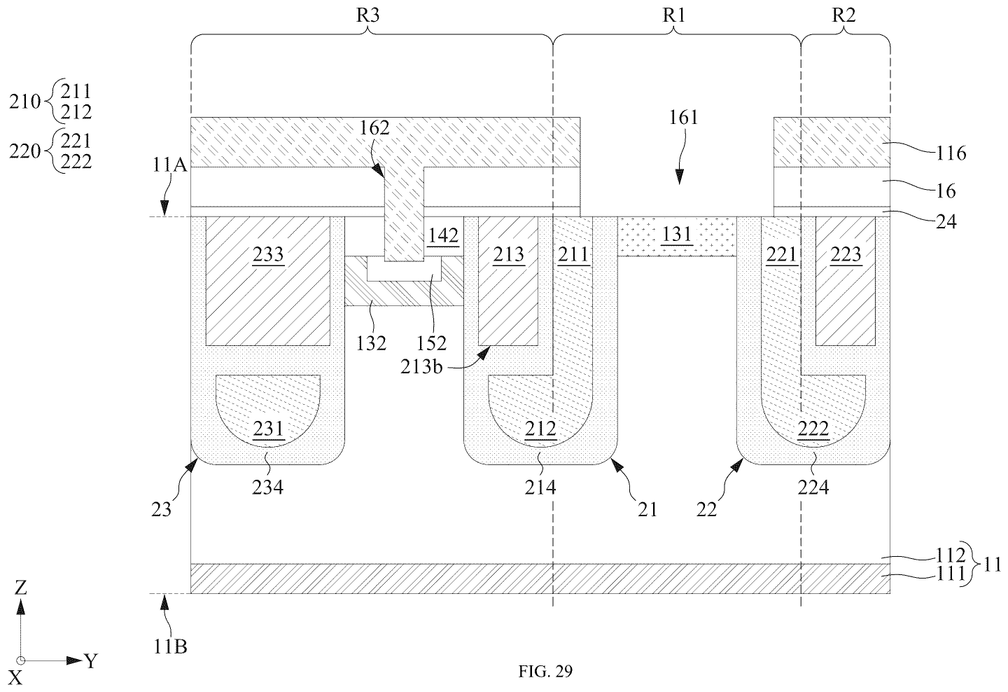

Referring to FIG. 29, the manufacturing method includes partially removing the interlayer dielectric layer 16 and the fourth oxide layer 24 in the first region R1 to form the first groove/opening 161. The first groove/opening 161 may be formed by one or more etching processes. The first groove/opening 161 is located on the electrode structures (i.e., the first electrode 210 and the second electrode 220) in the first region R1 between the first trench structure 21 and the second trench structure 22 and stops at the first surface 11A, exposing the first portion 211 of the first electrode 210 and the third portion 221 of the second electrode 220, respectively. The width of the first groove/opening 161 may be greater than the width of the second groove/opening 162. The first groove 161 is generally provided in the interlayer dielectric layer 16 and the fourth oxide layer 24, extending through the interlayer dielectric layer 16 and the fourth oxide layer 24. The width of the first groove 161 covers a portion of the first portion 211, the first doped region 131 and a portion of the second portion 221.

In some embodiments, a fourth patterned shielding layer 116 is formed on the interlayer dielectric layer 16 to define the position of the first groove/opening 161. The interlayer dielectric layer 16 and the fourth oxide layer 24 in the first region R1 may be partially removed by adjusting the position of the fourth patterned shielding layer 116. In some embodiments, the fourth patterned shielding layer 116 is formed by performing a photolithography process using a photomask having a corresponding pattern.

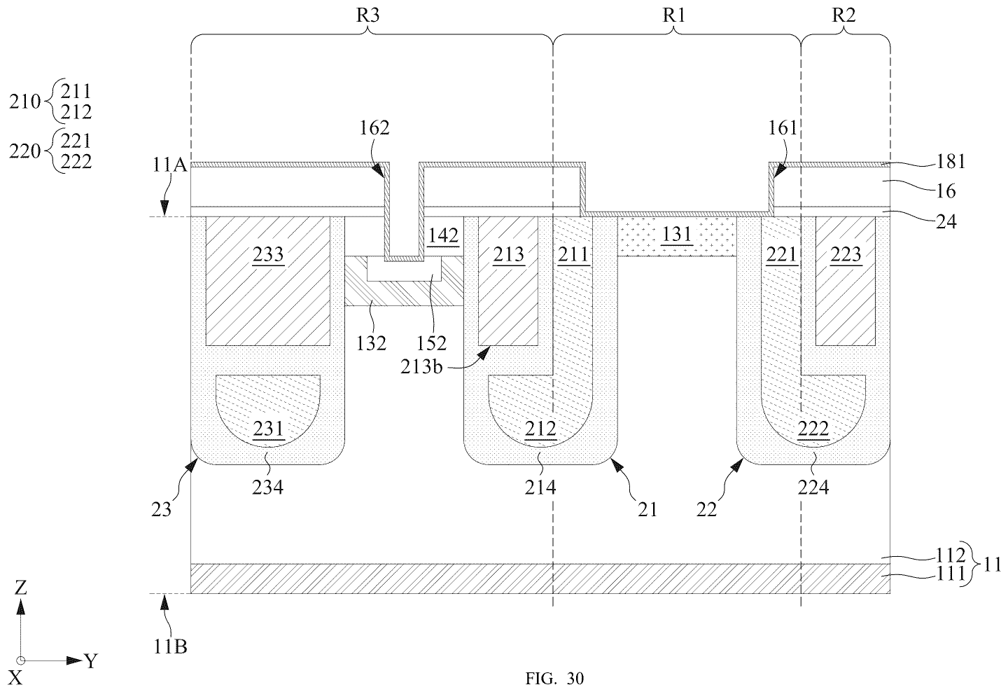

Referring to FIG. 30, the manufacturing method includes forming the shielding metal layer 181 on the interlayer dielectric layer 16 and in the first groove 161 and the second groove 162.

In some embodiments, the shielding metal layer 181 covers the interlayer dielectric layer 16. In some embodiments, the first in-trench oxide layer 181 may be formed by a thermal oxidation technology or other deposition processes, and the deposition processes may be, for example, ALD, CVD or other deposition methods. In some embodiments, the shielding metal layer 181 may be conformally deposited on the inner side surfaces of the first groove 161 and the second groove 162 (including the opposite sidewalls and the bottom extending between the sidewalls, for each groove). In some embodiments, the shielding metal layer 181 may be filled into the first groove 161 and the second groove 162 through a deposition process, such that the shielding metal layer 181 forms at least one groove in each of the first groove 161 and the second groove 162.

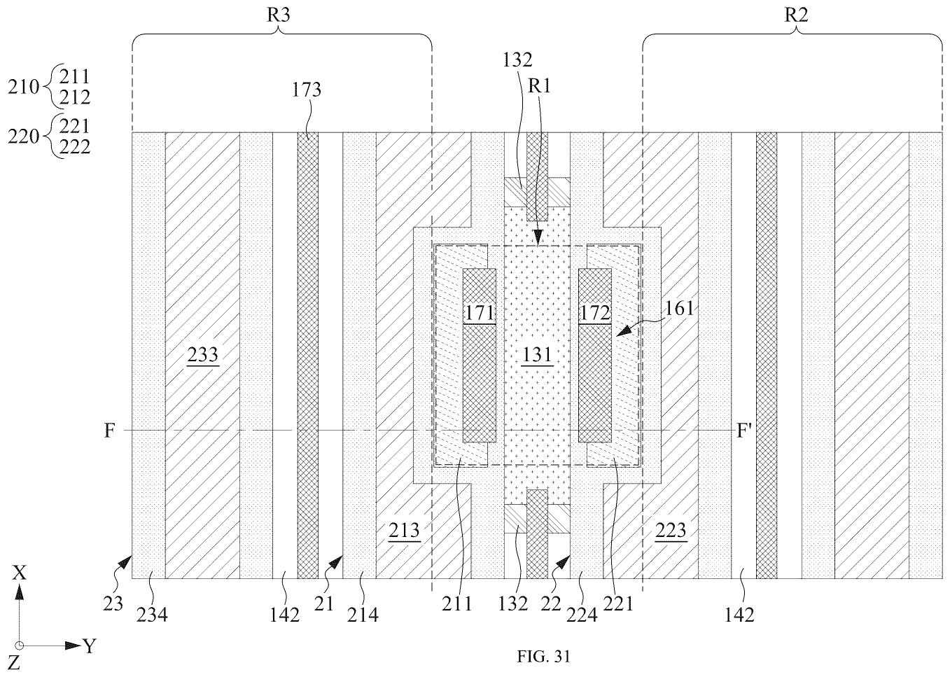

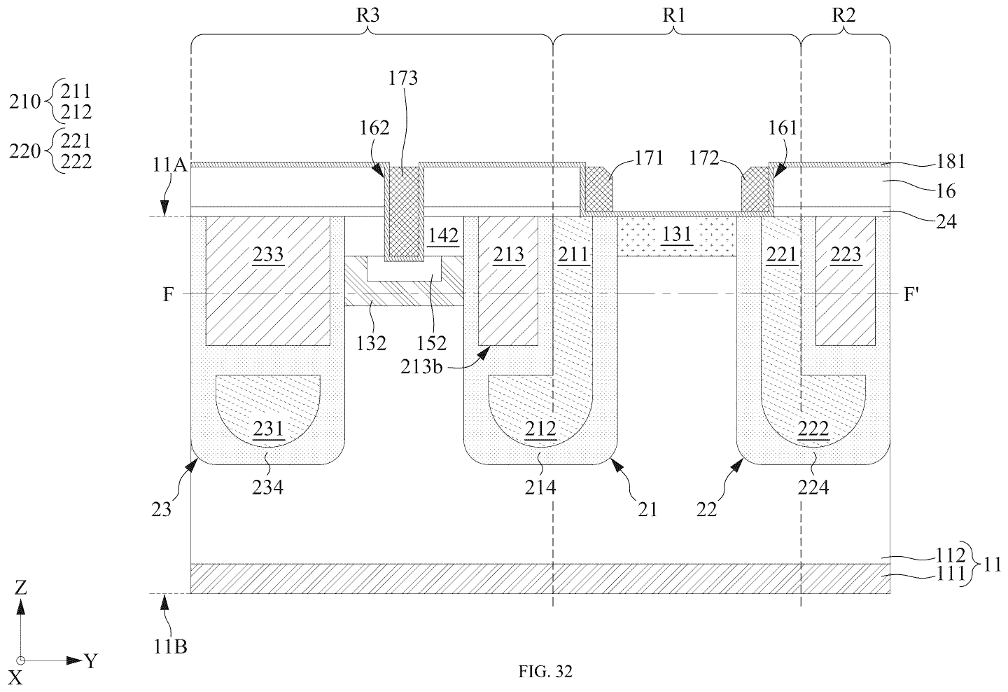

FIG. 31 is a top view of an example of a trench semiconductor structure in a stage of a manufacturing method of the trench semiconductor structure according to some embodiments of the present disclosure. FIG. 32 is a cross-sectional view of the trench semiconductor structure taken along a line F-F′ at the stage shown in FIG. 31 in the manufacturing method of the trench semiconductor structure according to some embodiments of the present disclosure. FIG. 31 and FIG. 32 are based on the trench semiconductor structure described with respect to FIG. 30, and show the trench semiconductor structure with further manufacturing processes performed subsequently, as discussed in the following.

Referring to FIG. 31 and FIG. 32, the manufacturing method includes forming the first conductive plug 171, the second conductive plug 172 in the first groove/opening 161, and forming the third conductive plug 173 in the second groove/opening 162. The first conductive plug 171 and the second conductive plug 172 may be formed on two sides of the first groove/opening 161 and are separated from each other. The first conductive plug 171 may be disposed on the first electrode 210 and the first oxide layer 214, and the second conductive plug 172 may be disposed on the second electrode 220 and the second oxide layer 224.

The first conductive plug 171, the second conductive plug 172 and the third conductive plug 173 may be formed by filling a conductive material into the first groove/opening 161 and the second groove/opening 162, respectively, through e.g., electroplating or CVD. The first conductive plug 171, the second conductive plug 172 and the third conductive plug 173 are formed on the shielding metal layer 181, and may be formed simultaneously or separately. The conductive material may include gold (Au), silver (Ag), copper (Cu), platinum (Pt), palladium (Pd), tungsten (W), titanium (Ti), tantalum (Ta), molybdenum (Mo) or other metals or alloys. In some embodiments, a planarization process may be selectively performed after electroplating or CVD. In some embodiments, the top surfaces of the first conductive plug 171, the second conductive plug 172 and the third conductive plug 173 are flush or located at approximately the same level. In some embodiments, the top surfaces of the first conductive plug 171, the second conductive plug 172 and the third conductive plug 173 are slightly lower than the height of the shielding metal layer 181. As an example, their tops surfaces are lower than the shielding metal layer 181 that is disposed on the top surfaces of the interlayer dielectric layer 16.

Referring to the top view of FIG. 31, the configurations of the first conductive plug 171 and the second conductive plug 172 are defined by the first groove/opening 161. The first conductive plug 171 overlaps with the first electrode 210 in the first region R1, and the second conductive plug 172 overlaps with the second electrode 220 in the first region R1. The configuration of the third conductive plug 173 is defined by the configuration of the second groove/opening 162, and thus has the same configuration as the second groove/opening 162. The third conductive plug 173 is surrounded by the third doped region 142 and the heavily doped region 152 in the third region R3.

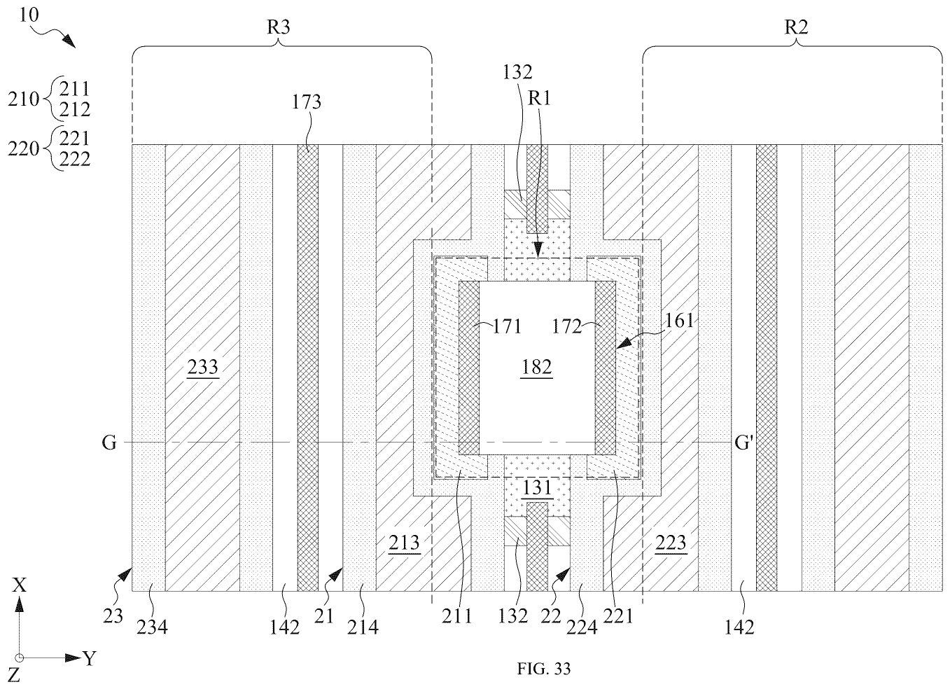

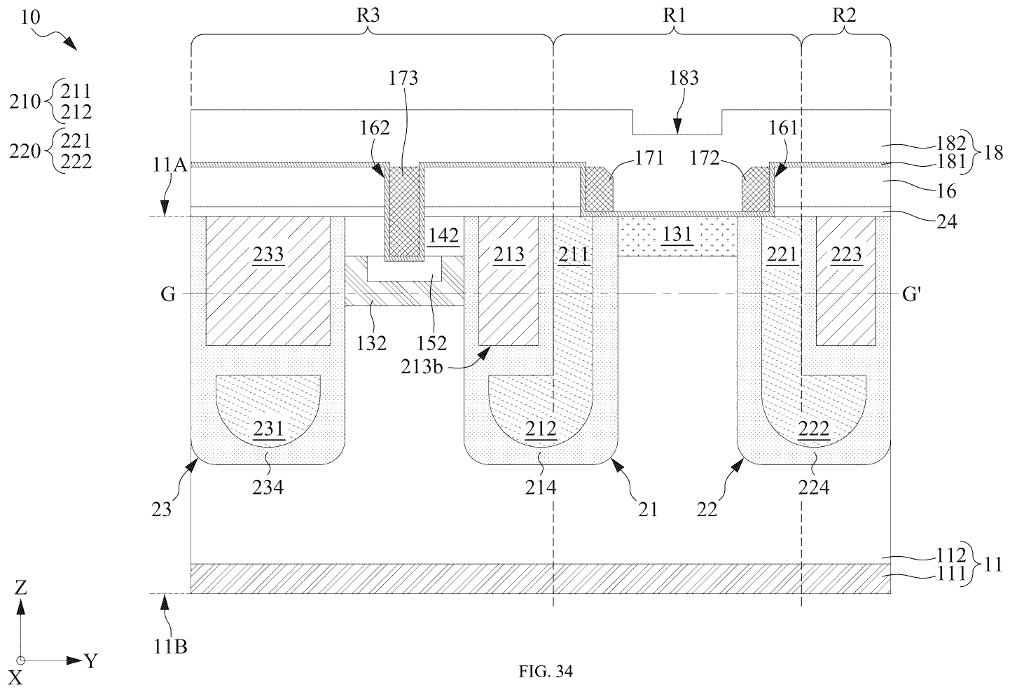

FIG. 33 is a top view of an example of a trench semiconductor structure in a stage of a manufacturing method of the trench semiconductor structure according to some embodiments of the present disclosure. FIG. 34 is a cross-sectional view of the trench semiconductor structure taken along a line G-G′ at the stage shown in FIG. 33 in the manufacturing method of the trench semiconductor structure according to some embodiments of the present disclosure. FIG. 33 and FIG. 34 are based on the trench semiconductor structure described with respect to FIGS. 31-32, and show the trench semiconductor structure with further manufacturing processes performed, as discussed in the following.

Referring to FIGS. 33 and 34, the manufacturing method includes forming the metal layer 182 over the interlayer dielectric layer 16 to form the trench semiconductor structure, e.g., the trench semiconductor structure 10 as shown in FIG. 2. The shielding metal layer 181 and the metal layer 182 constitute a conductive material layer. The metal layer 182 may be formed by electroplating or CVD, and the metal layer 182 may be patterned according to requirements of electrical properties and operations. The material of the metal layer 182 may include copper (Cu), gold (Au), silver (Ag), aluminum (Al), nickel (Ni), titanium (Ti), tungsten (W), tin (Sn) or other metals or alloys. In some embodiments, the metal layer 182 is defined as a plurality of metal wires by an etching process. In some embodiments, the metal layer 182 is in contact with and is electrically connected to the shielding metal layer 181, the first conductive plug 171, the second conductive plug 172, and the third conductive plug 173. The first conductive plug 171, the second conductive plug 172, and the third conductive plug 173 extend from the metal layer 182 in the vertical direction Z. The first conductive plug 171 is formed between the first trench structure 21 and the metal layer 182, the second conductive plug 172 is formed between the second trench structure 22 and the metal layer 182, and the third conductive plug 173 is formed between the second doped region 132 and the metal layer 182.

The trench semiconductor structure formed by the above steps can be basically the same as the semiconductor structure 10 shown in FIGS. 1 to 3. The trench semiconductor structure 10 has the first trench structure 21 including the first electrode 210 and the first gate 213, the second trench structure 22 including the second electrode 220 and the second gate 223. The first electrode 210 includes the first portion 211 adjacent to the first gate 213, and the second portion 212 located below the first portion 211 and the first gate 213 and connected to the first portion 211. The first doped region 131 is disposed between the first electrode 210 and the second electrode 220. The first electrode 210, the second electrode 220, the first doped region 131 and the above conductive material layer 18 form a TMBS. The trench semiconductor structure 10 integrates at least part of the TMBS and at least part of the SGT MOSFET in the same trench, improves the chip area utilization and achieves the effect of effectively using space. The following provides further embodiments.

According to one aspect of the present disclosure, an embodiment trench semiconductor structure is provided that includes: a semiconductor material layer having a first surface and a second surface opposite to the first surface, wherein the semiconductor material layer is of a first conductivity type; a first trench structure extending from the first surface towards the second surface, wherein the first trench structure includes a first electrode, a first gate, and a first oxide layer separating the first electrode from the first gate, the first electrode includes a first portion adjacent to the first gate and a second portion located below the first portion and the first gate and connected to the first portion; a first doped region, located in the semiconductor material layer adjacent to the first surface and adjacent to the first portion of the first electrode, wherein the first doped region is of a second conductivity type; an interlayer dielectric layer, disposed on the first surface of the semiconductor material layer and covering the first trench structure; a shielding metal layer, covering the interlayer dielectric layer and the first doped region, and contacting the first electrode; and a metal layer, on the interlayer dielectric layer and the first doped region, wherein the first portion of the first electrode is located between the first doped region and the first gate, and the first electrode and the first doped region are both in contact with the shielding metal layer to be electrically connected to the metal layer.

Optionally, in any of the preceding aspects, the first electrode and the first doped region form a trench MOS barrier Schottky (TMBS) diode.

Optionally, in any of the preceding aspects, the first portion and the second portion of the first electrode are formed integrally.

Optionally, in any of the preceding aspects, a width of the first portion of the first electrode is greater than a width of the second portion of the first electrode.

Optionally, in any of the preceding aspects, the trench semiconductor structure may further include: a groove located on the first doped region and the shielding metal layer and extending through the interlayer dielectric layer, wherein at least a portion of the metal layer and at least a portion of the shielding metal layer are located in the groove; and a first conductive plug located in the groove and electrically connected to the first electrode and the metal layer.

Optionally, in any of the preceding aspects, the trench semiconductor structure may further includes: a second trench structure extending from the first surface towards the second surface and disposed adjacent to the first trench structure, wherein the second trench structure comprises a second electrode, a second gate, and a second oxide layer separating the second electrode from the second gate, the second electrode comprises a third portion adjacent to the second gate, and a fourth portion located below the third portion and the second gate and connected to the third portion; and wherein the third portion of the second electrode is located between the second gate and the first doped region, and the second electrode is in contact with the shielding metal layer to be electrically connected to the metal layer.

Optionally, in any of the preceding aspects, a trench depth of the first trench structure is the same as a trench depth of the second trench structure.

Optionally, in any of the preceding aspects, a trench width of the first trench structure is the same as or different from a trench width of the second trench structure.

Optionally, in any of the preceding aspects, the first electrode, the second electrode and the first doped region form a trench MOS barrier Schottky (TMBS) diode.

Optionally, in any of the preceding aspects, the trench semiconductor structure may further include: a groove located on the first doped region and the shielding metal layer and extending through the interlayer dielectric layer; and a second conductive plug located in the groove and electrically connected to the second electrode and the metal layer, wherein at least part of the metal layer and at least part of the shielding metal layer are located in the groove and are electrically connected to the second conductive plug.

Optionally, in any of the preceding aspects, a width of the first gate is greater than a width of the first portion of the first electrode.

Optionally, in any of the preceding aspects, the trench semiconductor structure may further includes: a third trench structure extending from the first surface towards the second surface and disposed adjacent to the first trench structure, wherein the third trench structure comprises a third electrode, a third gate located on the third electrode, and a third oxide layer separating the third electrode and the third gate from each other; a second doped region, located in the semiconductor material layer, adjacent to the first surface and between the first trench structure and the third trench structure, wherein the second doped region is of the second conductivity type; a third doped region, located between the first surface and the second doped region, wherein the third doped region is of the first conductivity type; and a third conductive plug electrically connected to the second doped region and the metal layer, wherein the interlayer dielectric layer covers the third trench structure and the third doped region.

Optionally, in any of the preceding aspects, a doping concentration of the second doped region is greater than a doping concentration of the first doped region.

Optionally, in any of the preceding aspects, the first gate, the third electrode, the third gate, the second doped region, the third doped region and the third conductive plug form a shielded gate trench metal oxide semiconductor field effect transistor (SGT MOSFT).

Optionally, in any of the preceding aspects, at least a portion of the third conductive plug is surrounded by the third doped region and electrically connected to the metal layer.

Optionally, in any of the preceding aspects, the third conductive plug extends through the third doped region.

Optionally, in any of the preceding aspects, the first oxide layer located between the first portion of the first electrode and the semiconductor material layer has a first thickness, the first oxide layer located between the first gate and the semiconductor material layer has a second thickness, and the second thickness is less than the first thickness.

Optionally, in any of the preceding aspects, the trench semiconductor structure may further include: a fourth oxide layer located on the first surface of the semiconductor material layer and between the interlayer dielectric layer and the first trench structure.

According to another aspect of the present disclosure, a trench semiconductor structure is provided that includes: a semiconductor material layer having a first conductivity type, and having a first region and a second region surrounding the first region; a first trench structure, recessed into the semiconductor material layer, and comprising a first electrode, a first gate, and a first oxide layer surrounding the first electrode and the first gate, wherein the first electrode includes a first portion adjacent to the first gate, and a second portion overlapping with the first portion and the first gate and connected to the first portion when viewed from a top view; a second trench structure, recessed into the semiconductor material layer, and comprising a second electrode, a second gate, and a second oxide layer surrounding the second electrode and the second gate; and a first doped region disposed in the semiconductor material layer and between the first trench structure and the second trench structure, wherein the first doped region has a second conductivity type, wherein the first electrode and the second electrode are disposed between the first gate and the second gate, a part of the first electrode, a part of the second electrode, and the first doped region between the first electrode and the second electrode are located in the first region, and the first gate and the second gate are located in the second region.

Optionally, in any of the preceding aspects, the first region comprises a trench MOS barrier Schottky (TMBS) diode, and the second region comprises a shielded gate trench metal oxide semiconductor field effect transistor (SGT MOSFT).

Optionally, in any of the preceding aspects, the trench semiconductor structure may further include: a third trench structure, recessed into the semiconductor material layer, and comprising a third electrode, a third gate, and a third oxide layer surrounding the third electrode and the third gate and separating the third electrode and the third gate from each other, wherein the first electrode, the second electrode and the first gate extend along a first direction, and the third gate has a mesh structure, includes a fifth portion extending along the first direction and a sixth portion extending along a second direction different from the first direction.

Optionally, in any of the preceding aspects, a length of the first portion of the first electrode is the same as or different from a length of the third portion of the second electrode when viewed from a top view.

According to another aspect of the present disclosure, manufacturing method for a trench semiconductor structure is provided that includes: forming a first trench in a semiconductor material layer, wherein the first trench extends from a first surface towards a second surface; forming a first electrode in the first trench, wherein the first electrode comprises a first portion and a second portion located below the first portion and connected to the first portion; forming a first gate in the first trench, wherein the first gate is adjacent to the first portion of the first electrode and is located above the second portion of the first electrode, and the first electrode and the first gate form a first trench structure; forming a first doped region in the semiconductor material layer adjacent to the first surface, wherein the first doped region has a second conductivity type, and the first portion of the first electrode is located between the first doped region and the first gate; forming an interlayer dielectric layer on the first surface of the semiconductor material layer, wherein the interlayer dielectric layer covers the first trench structure and the first doped region; forming a groove extending through the interlayer dielectric layer to expose the first doped region and the first portion of the first electrode; forming a shielding metal layer in the groove and on the interlayer dielectric layer, wherein the shielding metal layer covers the interlayer dielectric layer and the first doped region and contacts the first portion of the first electrode; and forming a metal layer in the groove and on the interlayer dielectric layer and the shielding metal layer, wherein the first portion of the first electrode and the first doped region are in contact with the shielding metal layer to be electrically connected to the metal layer.

Optionally, in any of the preceding aspects, the first portion and the second portion of the first electrode are formed simultaneously.

Optionally, in any of the preceding aspects, the manufacturing method may further include: forming a first conductive plug between the first trench structure and the metal layer, wherein the first conductive plug is located in the groove and surrounded by the metal layer and the shielding metal layer, and is located on the first portion of the first electrode; and forming a second conductive plug in the groove, and separated from the first conductive plug and the first trench structure, wherein at least a portion of the metal layer is located between the first conductive plug and the second conductive plug.

Optionally, in any of the preceding aspects, the first conductive plug and the second conductive plug are formed simultaneously.

Optionally, in any of the preceding aspects, the manufacturing method may further include: forming a second trench in the semiconductor material layer, wherein the second trench extends from the first surface towards the second surface and is disposed adjacent to the first trench; forming a second electrode in the second trench, wherein the second electrode comprises a third portion and a fourth portion located below the third portion and connected to the third portion; and forming a second gate in the second trench, wherein the second gate is adjacent to the third portion of the second electrode and is located above the fourth portion of the second electrode, and the third portion, the fourth portion and the second gate of the second electrode form a second trench structure, wherein the first doped region is between the first trench structure and the second trench structure, the interlayer dielectric layer covers the second trench structure, and the groove exposes the third portion.

Optionally, in any of the preceding aspects, the first electrode and the second electrode are formed simultaneously.

Optionally, in any of the preceding aspects, forming the first trench structure in the first trench and forming the second trench structure in the second trench further include: forming a first oxide layer in the first trench, wherein the first electrode and the first gate are surrounded by the first oxide layer; and forming a second oxide layer in the second trench, wherein the second electrode and the second gate are surrounded by the second oxide layer.

Optionally, in any of the preceding aspects, the manufacturing method may further include: forming a third trench in the semiconductor material, wherein the third trench extends from the first surface towards the second surface, and the first trench is located between the third trench and the second trench; and forming a third electrode, a third gate located on the third electrode, and a third oxide layer surrounding the third electrode and the third gate and separating the third electrode and the third gate from each other; wherein the third electrode, the third gate and the third oxide layer form a third trench structure, and the first trench structure is located between the second trench structure and the third trench structure.

Optionally, in any of the preceding aspects, the manufacturing method may further include: forming a second doped region in the semiconductor material layer, wherein the second doped region has a second conductivity type and is located between the third gate and the first gate; forming a third doped region in the second doped region and adjoining a portion of the first surface of the semiconductor material layer, the third doped region being heavily doped with a first conductivity type; and forming a third conductive plug between the second doped region and the metal layer, wherein the third conductive plug extends from the metal layer, passes through the third doped region, and contacts the second doped region.

Optionally, in any of the preceding aspects, forming the first doped region is before forming the third doped region.

Optionally, in any of the preceding aspects, forming the first electrode is before forming the first gate.

According to the structures and processes of the present disclosure described above, and under the same purpose and concept, the steps in the above processes may be adjusted or orders of the steps may be changed to achieve the same or similar semiconductor structure.

In this disclosure, for description convenience, spatially relative terms such as “below”, “under”, “lower”, “above”, “upper”, “left side”, “right side”, and the like, may be used to describe the relationship of one component or feature with another one or more components or features, as shown in the accompanying drawings. The spatially relative terms are not only used to depict the orientations in the accompanying drawings, but also intended to encompass different orientations of a device in use or operation. A device may be oriented in other ways (rotated 90 degrees or in other orientations), and the spatially relative terms used herein may be interpreted in a corresponding way similarly. It should be understood that when a component is referred to as being “connected to” or “coupled to” another component, it may be directly connected or coupled to another component or an intervening component may be present.

As used herein, the terms “approximately”, “basically”, “substantially” and “about” are used to describe and account for small variations. When used in conjunction with an event or instance, the terms may refer to an embodiment of exact occurrence of an event or instance as well as an embodiment where the event or instance is close to occurrence. As used herein with respect to a given value or range, the term “about” generally means being within ±10%, ±5%, ±1%, or ±0.5% of the given value or range. A range herein may be referred to as being from one endpoint to the other or as being between two endpoints. All ranges disclosed herein are inclusive of the endpoints unless otherwise indicated. The term “substantially coplanar” may mean that the difference of positions of two surfaces with reference to the same plane is within a few micrometers (μm), e.g., within 10 μm, within 5 μm, within 1 μm, or within 0.5 μm. When values or characteristics are referred to as being “substantially” the same, the term may refer to a value that is within ±10%, ±5%, ±1%, or ±0.5% of the mean of the values.

The foregoing summarizes the features of several embodiments and detailed aspects of the present disclosure. The embodiments described in the present disclosure can be easily used as a basis for designing or modifying other processes and structures to facilitate the implementation of the same or similar purposes and/or to achieve the same or similar advantages of the embodiments presented herein. Such equivalent constructions do not depart from the spirit and scope of the present disclosure, and various changes, substitutions and modifications may be made without departing from the spirit and scope of the present disclosure. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, which may perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, or steps.

What is claimed:

1. A trench semiconductor structure, comprising:
a semiconductor material layer of a first conductivity type, the semiconductor material layer having a first surface and a second surface opposite to the first surface;
a first trench structure extending from the first surface towards the second surface, wherein the first trench structure includes a first electrode, a first gate, and a first oxide layer separating the first electrode from the first gate, and the first electrode includes a first portion and a second portion connected to the first portion, the first portion being adjacent to the first gate, and the second portion located below the first portion and the first gate;
a first doped region of a second conductivity type in the semiconductor material layer and adjacent to the first surface, wherein the first portion of the first electrode is located between the first doped region and the first gate;
an interlayer dielectric layer, disposed on the first surface of the semiconductor material layer and covering the first trench structure;
a shielding metal layer, covering the interlayer dielectric layer and the first doped region, and contacting the first electrode; and
a metal layer, disposed on the shielding metal layer, and covering the interlayer dielectric layer and the first doped region,
wherein the first electrode and the first doped region are in contact with the shielding metal layer and are electrically connected to the metal layer through the shielding metal layer.

2. The trench semiconductor structure according to claim 1, wherein the first electrode and the first doped region form a trench metal oxide semiconductor (MOS) barrier Schottky (TMBS) diode.

3. The trench semiconductor structure according to claim 1, wherein a width of the second portion of the first electrode is greater than a width of the first portion of the first electrode.

4. The trench semiconductor structure according to claim 1, further comprising:
a groove provided in the interlayer dielectric layer and extending through the interlayer dielectric layer, wherein the groove covers the first doped region and a portion of the first electrode, and a portion of the metal layer and a portion of the shielding metal layer are located in the groove; and
a first conductive plug located in the groove and electrically connected to the first electrode and the metal layer.

5. The trench semiconductor structure according to claim 1, further comprising:
a second trench structure extending from the first surface towards the second surface and adjacent to the first trench structure, wherein the second trench structure comprises a second electrode, a second gate, and a second oxide layer separating the second electrode from the second gate, the second electrode comprises a third portion and a fourth portion connected to the third portion, the third portion being adjacent to the second gate, and the fourth portion located below the third portion and the second gate; and
wherein the third portion of the second electrode is located between the second gate and the first doped region, and the second electrode is in contact with the shielding metal layer and is electrically connected to the metal layer through the shielding metal layer.

6. The trench semiconductor structure according to claim 5, wherein the first electrode, the second electrode and the first doped region form a trench MOS barrier Schottky (TMBS) diode.

7. The trench semiconductor structure according to claim 5, further comprising:
a groove extending through the interlayer dielectric layer covering a portion of the second electrode, wherein a portion of the metal layer and a portion of the shielding metal layer are located in the groove; and
a second conductive plug located in the groove and electrically connected to the second electrode and the metal layer.

8. The trench semiconductor structure according to claim 1, further comprising:
a third trench structure extending from the first surface towards the second surface, wherein the third trench structure comprises a third electrode, a third gate located over the third electrode, and a third oxide layer separating the third electrode and the third gate from each other;
a second doped region of the second conductivity type in the semiconductor material layer, the second doped region being adjacent to the first surface and between the first trench structure and the third trench structure;
a third doped region of the first conductivity type, located between the first surface and the second doped region; and
a third conductive plug, extending through the interlayer dielectric layer and the third doped region, and electrically connected to the second doped region and the metal layer, wherein the interlayer dielectric layer covers the third trench structure and the third doped region.

9. The trench semiconductor structure according to claim 8, wherein the first gate, the third electrode, the third gate, the second doped region, the third doped region and the third conductive plug form a shielded gate trench metal oxide semiconductor field effect transistor (SGT MOSFT).

10. The trench semiconductor structure according to claim 8, wherein at least a portion of the third conductive plug is surrounded by the third doped region.

11. The trench semiconductor structure according to claim 1, further comprising:
a fourth oxide layer on the first surface of the semiconductor material layer and between the interlayer dielectric layer and the first trench structure.

12. A trench semiconductor structure, comprising:
a semiconductor material layer of a first conductivity type, having a first region and a second region surrounding the first region;
a first trench structure, recessed from a first surface of the semiconductor material layer into the semiconductor material layer, and comprising a first electrode, a first gate, and a first oxide layer surrounding and separating the first electrode and the first gate, wherein the first electrode includes a first portion and a second portion connected to the first portion, the first portion being adjacent to the first gate, and the second portion overlapping with the first portion and the first gate in a top view of the trench semiconductor structure;
a second trench structure, recessed from the first surface of the semiconductor material layer into the semiconductor material layer, and comprising a second electrode, a second gate and a second oxide layer surrounding and separating the second electrode and the second gate; and
a first doped region of a second conductivity type, disposed in the semiconductor material layer, and between the first trench structure and the second trench structure; and
wherein the first electrode and the second electrode are disposed between the first gate and the second gate,
a portion of the first electrode, a portion of the second electrode, and the first doped region are located in the first region, and
the first gate and the second gate are located in the second region.

13. The trench semiconductor structure according to claim 12, wherein the first region comprises a trench metal oxide semiconductor (MOS) barrier Schottky (TMBS) diode formed by at least the first electrode, the second electrode and the first doped region, and the second region comprises a shielded gate trench metal oxide semiconductor field effect transistor (SGT MOSFT) formed by at least the second gate.

14. The trench semiconductor structure according to claim 12, further comprising:
a third trench structure, recessed from the first surface of the semiconductor material layer into the semiconductor material layer, and comprising a third electrode, a third gate, and a third oxide layer surrounding the third electrode and the third gate and separating the third electrode and the third gate from each other,
wherein the first electrode, the second electrode and the first gate extend along a first direction on a plane in parallel with the first surface, and the third gate includes a fifth portion extending along the first direction and a sixth portion extending along a second direction different from the first direction on the plane.

15. The trench semiconductor structure according to claim 12, wherein the second electrode includes a third portion and a fourth portion connected to the third portion, the third portion being adjacent to the second gate, and the fourth portion overlapping with the third portion and the second gate in the top view of the trench semiconductor structure.

16. A method of manufacturing a trench semiconductor structure, comprising:
forming a first trench in a semiconductor material layer of a first conductivity type, wherein the first trench extends from a first surface of the semiconductor material layer towards a second surface of the semiconductor material layer opposite to the first surface;
forming a first electrode in the first trench, wherein the first electrode comprises a first portion, and a second portion located below the first portion and connected to the first portion;
forming a first gate in the first trench, wherein the first gate is adjacent to the first portion of the first electrode and above the second portion of the first electrode, and the first electrode and the first gate form a first trench structure;
forming a first doped region of a second conductivity type in the semiconductor material layer adjacent to the first surface, wherein the first portion of the first electrode is located between the first doped region and the first gate;
forming an interlayer dielectric layer on the first surface of the semiconductor material layer, wherein the interlayer dielectric layer covers the first trench structure and the first doped region;
forming a groove extending through the interlayer dielectric layer, the first groove exposing the first doped region and the first portion of the first electrode;
forming a shielding metal layer in the groove and on the interlayer dielectric layer, wherein the shielding metal layer covers the interlayer dielectric layer and the first doped region; and
forming a metal layer in the groove and on the shielding metal layer,
wherein the first portion of the first electrode and the first doped region are in contact with the shielding metal layer and electrically connected to the metal layer.

17. The method according to claim 16, further comprising:
forming a first conductive plug in the groove between the first trench structure and the metal layer, wherein the first conductive plug is surrounded by the metal layer and the shielding metal layer, and is located over the first portion of the first electrode; and
forming a second conductive plug in the groove, the second conductive plug being separated from the first conductive plug by at least a portion of the metal layer disposed in the groove.

18. The method according to claim 16, further comprising:
forming a second trench in the semiconductor material layer, wherein the second trench extends from the first surface towards the second surface and is adjacent to the first trench;
forming a second electrode in the second trench, wherein the second electrode comprises a third portion, and a fourth portion located below the third portion and connected to the third portion; and
forming a second gate in the second trench, wherein the second gate is adjacent to the third portion of the second electrode and above the fourth portion of the second electrode, and the second electrode and the second gate form a second trench structure,
wherein the first doped region is between the first trench structure and the second trench structure, the interlayer dielectric layer covers the second trench structure, and the groove exposes the third portion of the second electrode.

19. The method according to claim 16, further comprising:
forming a third trench in the semiconductor material, wherein the third trench extends from the first surface towards the second surface, and the first trench is located between the third trench and the second trench; and
forming a third electrode, a third gate and a third oxide layer in the third trench, wherein the third gate is located over the third electrode, and the third oxide layer surrounds the third electrode and the third gate and separates the third electrode and the third gate from each other; and
wherein the third electrode, the third gate and the third oxide layer form a third trench structure, and the first trench structure is located between the second trench structure and the third trench structure.

20. The method according to claim 19, further comprising:
forming a second doped region of the second conductivity type in the semiconductor material layer and between the third gate and the first gate;
forming a third doped region in the second doped region and adjoining the first surface of the semiconductor material layer, the third doped region being a heavily doped region of the first conductivity type; and
forming a third conductive plug between the second doped region and the metal layer, wherein the third conductive plug extends from the metal layer, passes through the third doped region, and contacts the second doped region.
